(19) United States
(12) Patent Application Publication
(10) Pub. No.: US 2026/0182058 A1
(43) Pub. Date: Jun. 25, 2026

(54) PHOTODETECTION ELEMENT AND ELECTRONIC DEVICE

(71) Applicant: Sony Semiconductor Solutions Corporation, Kanagawa (JP)

(72) Inventors: Ryosuke MATSUMOTO, Kanagawa (JP); Keigo NAKAMURA, Kanagawa (JP); Yusuke OHTSUKA, Tokyo (JP)

(21) Appl. No.: 19/128,673

(22) PCT Filed: Oct. 31, 2023
(86) PCT No.: PCT/JP2023/039178

§ 371 Date: May 9, 2025

(30) Foreign Application Priority Data
Dec. 21, 2022 (JP) 2022-204825

(51) Int. Cl. H10F 39/00

(52) U.S. Cl. CPC H10F 39/8057; H10F 39/024; H10F 39/804

(57) ABSTRACT

The present disclosure provides a photodetection element and an electronic device capable of suppressing color mixing.

In order to solve the above problems, according to the present disclosure, there is provided a photodetection element including: a photoelectric conversion layer that generates a signal charge in response to incidence of light; and a light shielding structure having a wall shape and penetrating the photoelectric conversion layer, the light shielding structure having an opening on a side opposite to a light incident side and formed in a through hole having a groove shape and having a closed region on the light incident side.

### TECHNICAL FIELD

The present disclosure relates to a photodetection element and an electronic device.

### BACKGROUND ART

In recent years, an image sensor (photodetection element) using a semiconductor such as indium gallium arsenide (InGaAs) for a photoelectric conversion layer has attracted attention.

However, since the photoelectric conversion layer is provided as a common layer for each pixel, there is a possibility that color mixing occurs due to a difference between a pixel on which light is incident and a pixel from which a signal charge generated in the photoelectric conversion layer is extracted.

### CITATION LIST

### Patent Document

Patent Document 1: Japanese Patent Application No. 2019-518800

### SUMMARY OF THE INVENTION

### Problems to be Solved by the Invention

The present disclosure provides a photodetection element and an electronic device capable of suppressing color mixing.

### Solutions to Problems

In order to solve the above problems, according to the present disclosure,
there is provided a photodetection element including:
a photoelectric conversion layer that generates a signal charge in response to incidence of light; and
a light shielding structure having a wall shape and penetrating the photoelectric conversion layer, the light shielding structure having an opening on a side opposite to a light incident side and formed in a through hole having a groove shape and having a closed region on the light incident side.

The photodetection element may further include an insulating film formed on the light incident side of the photoelectric conversion layer, in which
an end of the light shielding structure having a wall shape on the light incident side is formed in the insulating film.

The photodetection element may further include a first semiconductor layer configured on the light incident side of the photoelectric conversion layer, in which
the light shielding structure having a wall shape further penetrates the first semiconductor layer.

The photodetection element may further include a second semiconductor layer configured on a side of the photoelectric conversion layer opposite to the light incident side, in which
the light shielding structure having a wall shape further penetrates the second semiconductor layer.

The photodetection element may further include:
a plurality of first conductivity type regions to which signal charges generated in the photoelectric conversion layer move; and
a second conductivity type region provided between the light shielding structures having a wall shape adjacent to each other while penetrating the photoelectric conversion layer.

The photoelectric conversion layer may be of a second conductivity type,
the second conductivity type region may have a higher concentration than the photoelectric conversion layer, and
the second conductivity type region may be formed in the second semiconductor layer.

The photodetection element may further include a transparent electrode configured on the light incident side of the photoelectric conversion layer, in which
the light shielding structure having a wall shape penetrates the transparent electrode.

The insulating film may include any of silicon oxide (SiO2), silicon nitride (SiN), aluminum oxide (Al2O3), and hafnium oxide (HfO2).

A total film thickness of the insulating film may be 50 to 300 nm.

The photoelectric conversion layer may be of a first conductivity type.

A sidewall protective film may be further provided between an inner wall in the through hole having a groove shape and the light shielding structure having a wall shape.

The sidewall protective film may be an insulating film doped with phosphorus (P), and the insulating film doped with phosphorus (P) may contain at least one of phosphorated quartz nitrite (PSG: Phosphorous Glass), phosphorus nitride (PN), and phosphorus oxide (PO).

The sidewall protective film may be an insulating film doped with phosphorus (P), and has a film thickness of 2 to 20 nm, and a doping concentration of phosphorus may be, for example, 1e20˜22 cm−3.

The second conductivity type region and at least the second conductivity type region of the light shielding structure may be electrically connected to a readout circuit unit.

The photodetection element may further include a color filter provided between the light shielding structures having a wall shape adjacent to each other while penetrating the photoelectric conversion layer.

An end of the light shielding structure on the light incident side may have a region in which a cross-sectional area increases from an incident side toward an opposite side.

In order to solve the above problems, according to the present disclosure,
there is provided a photodetection element including:
a photoelectric conversion layer that has at least one of indium gallium arsenide (InGaAs) or indium phosphide (InP) and generates a signal charge in response to incidence of light;
a light shielding structure having a wall shape and formed in a through hole having a groove shape and penetrating the photoelectric conversion layer; and
a sidewall protective film formed between an inner wall in the through hole having a groove shape and the light shielding structure having a wall shape, in which
the sidewall protective film is an insulating film doped with phosphorus (P).

In order to solve the above problems, according to the present disclosure,
there is provided a method for manufacturing a photodetection element, the method including:
forming a first temporary substrate, an initial insulating film, a first semiconductor layer, a photoelectric conversion layer, a second semiconductor layer, a protective film, and a second temporary substrate in layers;
deleting the first temporary substrate and the initial insulating film;
forming a first insulating film on a surface side of the first semiconductor layer opposite to the photoelectric conversion layer;
forming a through hole having a groove shape and penetrating the second semiconductor layer, the photoelectric conversion layer, and the first semiconductor layer from the second semiconductor layer side and stopping at the first insulating film; and
forming a protective film having a wall shape and a light shielding body from the second semiconductor layer side in the through hole having a groove shape.

In order to solve the above problems, according to the present disclosure,
there is provided a method for manufacturing a photodetection element, the method including:
forming at least a temporary substrate, a protective film, a photoelectric conversion layer, and an insulating film;
forming a through hole having a groove shape and penetrating the insulating film and the photoelectric conversion layer from a side of the insulating film and stopping at the protective film;
forming a wall shape and a light shielding body from the side of the insulating film in the through hole having a groove shape; and
etching ends of the insulating film, the protective film, and the light shielding body so that the insulating film has a flat surface.

According to the present disclosure,
there is provided an electronic device including:
a photodetection element; and
an optical system that focuses light on the photodetection element.

### BRIEF DESCRIPTION OF DRAWINGS

FIG. 1 is a configuration diagram illustrating an example of an electronic device according to a first embodiment of the present technology.

FIG. 2 is a diagram illustrating a configuration example of an imaging element.

FIG. 3 is a diagram illustrating an arrangement example of color filters according to the present embodiment.

FIG. 4 is a view illustrating an example of a cross-sectional view of a photodetection element.

FIG. 5 is an AA cross-sectional view of FIG. 6.

FIG. 6 is a plan view of four adjacent pixels p.

FIG. 7 is a cross-sectional view of a partial region of a second insulating film and a first insulating film.

FIG. 8 is a BB cross-sectional view of FIG. 7.

FIG. 9 is a cross-sectional view of a partial region of a first insulating film 43.

FIG. 10 is a BB cross-sectional view of FIG. 9.

FIG. 11 is a cross-sectional view from a part of a transparent electrode to a layer wiring board.

FIG. 12 is a BB cross-sectional view of FIG. 11.

FIG. 13 is a schematic cross-sectional view for explaining manufacturing steps of a photodetection element 1a (see FIG. 4) according to the present embodiment.

FIG. 14 is a schematic cross-sectional view illustrating steps subsequent to FIG. 13.

FIG. 15 is a schematic cross-sectional view illustrating steps subsequent to FIG. 14.

FIG. 16 is a schematic cross-sectional view illustrating steps subsequent to FIG. 15.

FIG. 17 is a schematic cross-sectional view for explaining a step of manufacturing a third electrode.

FIG. 18 is a schematic cross-sectional view illustrating steps subsequent to FIG. 17.

FIG. 19 is a schematic cross-sectional view for explaining other manufacturing steps of the third electrode.

FIG. 20 is a schematic cross-sectional view illustrating steps subsequent to FIG. 19.

FIG. 21 is a schematic cross-sectional view for explaining other manufacturing steps in a photodetection element.

FIG. 22 is a schematic cross-sectional view illustrating steps subsequent to FIG. 21.

FIG. 23 is a schematic cross-sectional view for explaining still other manufacturing steps in the photodetection element.

FIG. 24 is a schematic cross-sectional view illustrating steps subsequent to FIG. 23.

FIG. 25 is a diagram illustrating a configuration example of an optical element configured in a peripheral region of the photodetection element.

FIG. 26 is a view illustrating an example of a cross-sectional view of a photodetection element according to a second embodiment.

FIG. 27 is a BB cross-sectional view of FIG. 28.

FIG. 28 is a cross-sectional view of four adjacent pixels p.

FIG. 29 is a schematic cross-sectional view for explaining manufacturing steps of the photodetection element (FIG. 26).

FIG. 30 is a schematic cross-sectional view illustrating steps subsequent to FIG. 29.

FIG. 31 is a schematic cross-sectional view illustrating steps subsequent to FIG. 30.

FIG. 32 is a schematic cross-sectional view illustrating steps subsequent to FIG. 31.

FIG. 33 is a schematic cross-sectional view illustrating steps subsequent to FIG. 32.

FIG. 34 is a schematic cross-sectional view illustrating steps subsequent to FIG. 33.

FIG. 35 is a schematic cross-sectional view for explaining other manufacturing steps of the photodetection element (FIG. 26).

FIG. 36 is a cross-sectional view illustrating a partial structure example of a photodetection element in which an electrode layer 43b is formed.

FIG. 37 is a cross-sectional view illustrating a partial structure example of still another photodetection element.

FIG. 38 is a cross-sectional view illustrating an example formed using an insulating film doped with phosphorus.

FIG. 39 is another cross-sectional view illustrating an example formed using an insulating film doped with phosphorus.

FIG. 40 is still another cross-sectional view illustrating an example formed using an insulating film doped with phosphorus.

FIG. 41 is a partial cross-sectional view of a photodetection element according to a third embodiment.

FIG. 42A is an AA cross-sectional view of FIG. 42B.

FIG. 42B is a plan view of four adjacent pixels.

FIG. 43A is a cross-sectional view of a partial region of a transparent electrode, a first insulating film, and a second insulating film.

FIG. 43B is a BB cross-sectional view of FIG. 43A.

FIG. 44A is a cross-sectional view of a partial region of a photoelectric conversion layer, a protective film, a transparent electrode, a first insulating film, and a second insulating film.

FIG. 44B is a BB cross-sectional view of FIG. 44A.

FIG. 45A is a cross-sectional view of a partial region of the photoelectric conversion layer, the protective film, the transparent electrode, the first insulating film, the second insulating film, and a layer wiring portion.

FIG. 45B is a BB cross-sectional view of FIG. 45A.

FIG. 46 is a schematic cross-sectional view for explaining manufacturing steps of a photodetection element according to a third embodiment.

FIG. 47 is a schematic cross-sectional view illustrating steps subsequent to FIG. 46.

FIG. 48 is a schematic cross-sectional view illustrating steps subsequent to FIG. 47.

FIG. 49 is a schematic cross-sectional view illustrating steps subsequent to FIG. 48.

FIG. 50 is a schematic cross-sectional view illustrating steps subsequent to FIG. 49.

FIG. 51 is a schematic cross-sectional view illustrating steps subsequent to FIG. 50.

FIG. 52 is a cross-sectional view illustrating an example of a photodetection element in which a color filter is formed in a first insulating film.

FIG. 53 is a schematic cross-sectional view for explaining other manufacturing steps of the photodetection element.

FIG. 54 is a schematic cross-sectional view illustrating steps subsequent to FIG. 53.

FIG. 55 is a schematic cross-sectional view illustrating steps subsequent to FIG. 54.

FIG. 56 is a schematic cross-sectional view for explaining other manufacturing steps of the photodetection element.

FIG. 57 is a schematic cross-sectional view illustrating steps subsequent to FIG. 56.

FIG. 58 is a schematic cross-sectional view illustrating steps subsequent to FIG. 57.

FIG. 59 is a schematic cross-sectional view illustrating steps subsequent to FIG. 58.

FIG. 60 is a partial cross-sectional view of a photodetection element according to a fourth embodiment.

FIG. 61 is a BB cross-sectional view of FIG. 62.

FIG. 62 is an AA cross-sectional view of FIG. 61.

FIG. 63 is a schematic cross-sectional view for explaining manufacturing steps of a photodetection element according to a fourth embodiment.

FIG. 64 is a schematic cross-sectional view illustrating steps subsequent to FIG. 63.

FIG. 65 is a schematic cross-sectional view illustrating steps subsequent to FIG. 64.

FIG. 66 is a schematic cross-sectional view illustrating steps subsequent to FIG. 65.

FIG. 67 is a cross-sectional view illustrating an example in which a color filter and a second protective film are formed.

FIG. 68 is a cross-sectional view illustrating an example in which a shape of an end of a protruding portion of a second electrode is changed.

FIG. 69 is a cross-sectional view illustrating an example in which a transparent electrode is formed while leaving a part of a bonding insulating film at the protruding portion.

FIG. 70 is a cross-sectional view illustrating an example in which a transparent electrode is formed while leaving a part of a bonding insulating film at the protruding portion.

FIG. 71 is a cross-sectional view illustrating an example in which the conductivity type is different.

FIG. 72 is a diagram illustrating an arrangement example of a temperature monitoring circuit and a VBD monitoring circuit according to a ninth embodiment.

FIG. 73 is a block diagram illustrating an example of a schematic configuration of a patient in-vivo information acquisition system using a capsule endoscope to which the technology according to the present disclosure (present technology) can be applied.

FIG. 74 is a block diagram illustrating a schematic configuration example of a vehicle control system as an example of a moving body control system to which the technology according to the present disclosure can be applied.

FIG. 75 is a diagram illustrating an example of an installation position of an imaging section.

### MODE FOR CARRYING OUT THE INVENTION

Hereinafter, embodiments of a photodetection element and an electronic device will be described with reference to the drawings. Although principal configuration parts of the photodetection element and the electronic device will be mainly described below, the photodetection element and the electronic device may include configuration parts and functions that are not illustrated or described. The following description is not intended to exclude configuration parts and functions that are not illustrated or described.

### First Embodiment

### [Configuration Example of Electronic Device]

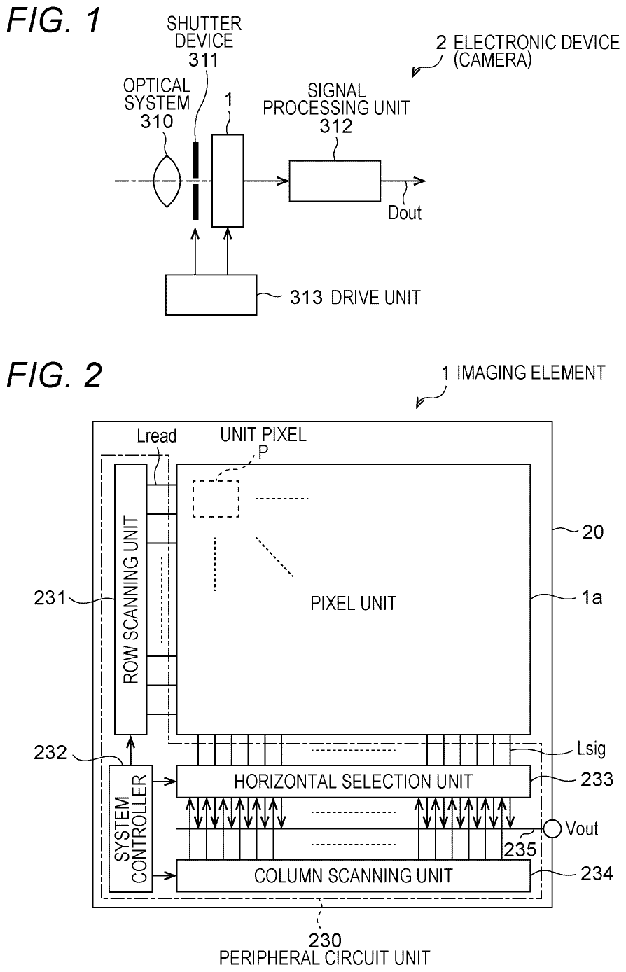

FIG. 1 is a configuration diagram illustrating an example of an electronic device according to the present embodiment. As illustrated in FIG. 1, an electronic device 2 is, for example, a camera capable of capturing a still image or a moving image, and includes an imaging element 1, an optical system (optical lens) 310, a shutter device 311, a drive unit 313 that drives the imaging element 1 and the shutter device 311, and a signal processing unit 312.

The optical system 310 guides image light (incident light) from a subject to the imaging element 1. The optical system 310 may include a plurality of optical lenses. The shutter device 311 controls a light irradiation period and a light shielding period for the imaging element 1. The drive unit 313 controls a transfer operation of the imaging element 1 and a shutter operation of the shutter device 311. The signal processing unit 312 performs various types of signal processing on a signal output from the imaging element 1. The video signal Dout after the signal processing is stored in a storage medium such as a memory or output to a monitor or the like.

### [Configuration Example of Imaging Element]

FIG. 2 is a diagram illustrating a configuration example of the imaging element 1 in the above embodiment and the like. As illustrated in FIG. 2, a functional configuration of the imaging element 1 is illustrated. The imaging element 1 is, for example, an image sensor, and includes, for example, a photodetection element 1a and a peripheral circuit unit 230 that drives the image portion (photodetection element) 1a on a substrate 20. The peripheral circuit unit 230 includes a row scanning unit 231, a horizontal selection unit 233, a column scanning unit 234, and a system controller 232.

The photodetection element 1a includes, for example, a plurality of unit pixels P two-dimensionally arranged in a matrix pattern. Hereinafter, the unit pixels P are simply referred to as pixels P. In the pixels P, a pixel drive line Lread (for example, a row selection line and a reset control line) is wired for each pixel row, and a vertical signal line Lsig is wired for each pixel column. The pixel drive line Lread transmits a drive signal for reading a signal from the pixel P. One end of the pixel drive line Lread is connected to an output end corresponding to each row of the row scanning unit 231. Note that, in the present embodiment, the photodetection element 1a may be referred to as a photodetection element.

The row scanning unit 231 includes a shift register, an address decoder, and the like, and is a pixel drive section that drives each pixel P of the photodetection element 1a, for example, in units of rows. Signals output from the pixels P of the pixel row selectively scanned by the row scanning unit 231 are supplied to the horizontal selection unit 233 through the vertical signal lines Lsig. The horizontal selection unit 233 includes an amplifier, a horizontal selection switch, and the like provided for each vertical signal line Lsig.

The column scanning unit 234 includes a shift register, an address decoder, and the like, and sequentially drives each horizontal selection switch of the horizontal selection unit 233 while scanning. By the selective scanning by the column scanning unit 234, a signal of each pixel transmitted through each of the vertical signal lines Lsig is sequentially output to a horizontal signal line 235 and input to a signal processing unit (not illustrated) or the like through the horizontal signal line 235.

The system controller 232 receives a clock provided from the outside, data instructing an operation mode, and the like, and outputs data such as internal information of the imaging element 1. The system controller 232 further includes a timing generator that generates various timing signals, and performs drive control of the row scanning unit 231, the horizontal selection unit 233, the column scanning unit 234, and the like on the basis of the various timing signals generated by the timing generator.

### [Example of Arrangement of Color Filters]

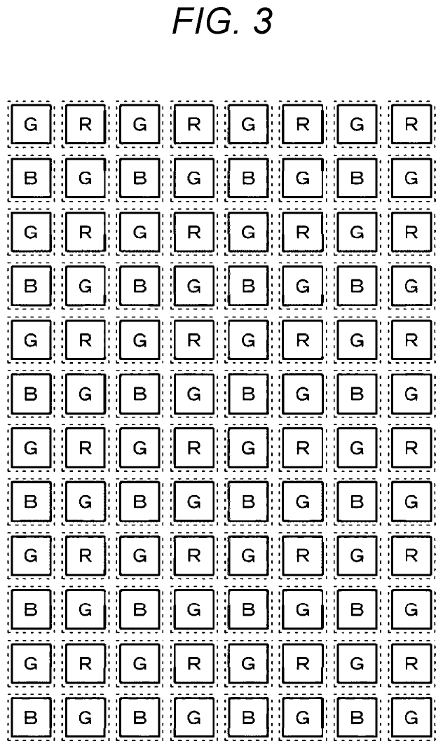

FIG. 3 is a diagram illustrating an arrangement example of color filters according to the present embodiment. Color filters R, G, and B are arranged in each of the pixels P illustrated in FIG. 2. The color filter R is a red filter and transmits light in a red band. The color filter G is a green filter and transmits light in a green band. The color filter B is a blue filter and transmits light in a blue band. In this manner, the color filter can be arranged for each pixel P. Note that the arrangement of these color filters is an example, and is not limited to these configurations and arrangements.

### [Configuration Example of Photodetection Element]

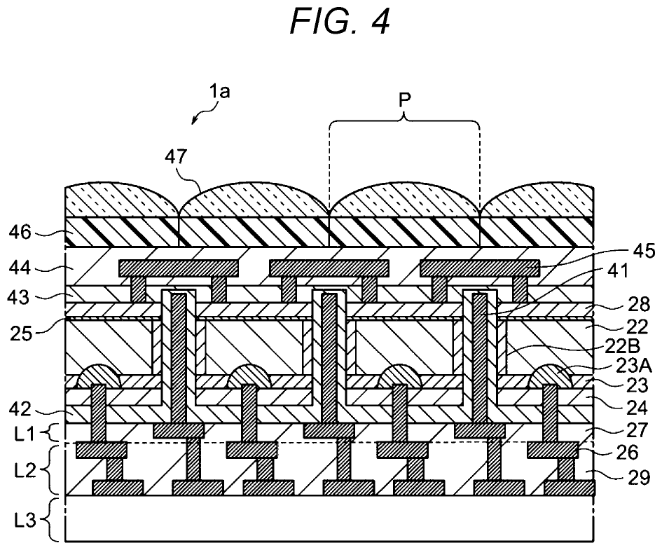

FIG. 4 is a diagram illustrating an example of a partial cross-sectional view of the photodetection element according to the present embodiment. The photodetection element 1a is applied to, for example, an infrared sensor or the like, and includes a plurality of pixels P (see FIG. 2) arranged two-dimensionally.

The photodetection element 1a has a photoelectric conversion layer 22, and a cap layer 23, a protective film 24, and a sidewall protective film 42 are sequentially formed on one surface of the photoelectric conversion layer 22. The sidewall protective film 42 is formed continuously from the sidewall of the groove to one surface of the protective film 24.

Layer wiring boards L1, L2, and L3 are sequentially formed on one surface of the sidewall protective film 42. In the photoelectric conversion layer 22 and the cap layer 23, a first conductivity type region 23A is provided for each pixel P. The photodetection element 1a has a first electrode 26 penetrating the protective film 24 and the sidewall protective film 42, and the first conductivity type region 23A and a ROIC (Readout Integrated Circuit) of the multilayer wiring board L3 are electrically connected by the first electrode 26. Each of the layer wiring boards L1 and L2 includes insulating films 27 and 29. The insulating films 27 and 29 are configured to include wiring and parts of the first electrode 26 and a second electrode 41 described later. Note that the ROIC according to the present embodiment corresponds to a read circuit unit. In addition, the second electrode 41 according to the present embodiment corresponds to a wall-shaped light shielding structure. Furthermore, it is also possible to use the second electrode 41 without applying a voltage to the second electrode 41, and in this case, it may be referred to as a light shielding body.

On the other surface of the photoelectric conversion layer 22, a compound semiconductor layer 25, a transparent electrode 28, a first insulating film 43, a second insulating film 44, a color filter 46 (see FIG. 3), and an on-chip lens 47 are provided in this order. The photoelectric conversion layer 22, the cap layer 23, and the compound semiconductor layer 25 are continuously formed for each pixel P, for example.

### [Light-Shielding Structure]

A through hole penetrating the photoelectric conversion layer 22, the cap layer 23, the compound semiconductor layer 25, and the transparent electrode 28 and stopping at the first insulating film 43 is provided between the adjacent pixels P. The sidewall protective film 42 and the second electrode 41 as a light shielding structure are embedded in the through hole. Further, the second electrode 41 penetrates the protective film 24 and the sidewall protective film 42, and is electrically connected to a read out integrated circuit (ROIC) of the multilayer wiring board L3.

The second electrode 41 is provided between the pixels P adjacent to each other, and is provided in, for example, a lattice shape in plan view as described later. Light enters the photoelectric conversion layer 22 from between the adjacent second electrodes 41. In this manner, by forming the light shielding structure penetrating the photoelectric conversion layer 22, the cap layer 23, and the compound semiconductor layer 25 between the pixels P, color mixing between the pixels P is suppressed. In general, a light shielding structure penetrating the cap layer 23 and the compound semiconductor layer 25 is not formed, and the influence of color mixing may become greater in a case where a highly accurate photodetection element is formed or high resolution is promoted. On the other hand, since the second electrode 41 which is the light shielding structure according to the present embodiment penetrates the cap layer 23 and the compound semiconductor layer 25, color mixing can be further suppressed. Note that, in the present embodiment, the charge to be separated into one pixel being transferred to the other pixel is referred to as color mixing.

In addition, since the second electrode 41 penetrates the photoelectric conversion layer 22, the cap layer 23, and the compound semiconductor layer 25, the pinning effect by the second electrode 41 is increased, and the dark current can be further reduced. Furthermore, these phenomena can be controlled by the potential applied to the second electrode 41.

### [First Insulating Film]

The first insulating film 43 includes a material having an insulating property and capable of suppressing variation in the protruding amount of the through hole when the through hole is formed. That is, the first insulating film 43 is configured by a film having a better processing selection ratio. Note that, since the through hole is formed in a groove shape around each pixel p, the through hole may be referred to as a groove-shaped through hole.

Examples of the film type of the first insulating film 43 include silicon oxide (SiO₂), silicon nitride (SiN), aluminum oxide (Al₂O₃), and hafnium oxide (HfO₂). Further, the total film thickness is, for example, 50 to 300 nm. As a result, when the through hole is formed from the opposite side of the light receiving surface, the protruding amount of the through hole on the light incident side can be made uniform. As can be seen from the above, since the protruding amount of the second electrode 41, which is the light shielding structure on the incident light side, can be made uniform, variation in the light incident amount of each pixel P is suppressed.

In this manner, by forming the wall-shaped light shielding structure that penetrates the photoelectric conversion layer 22, the cap layer 23, the compound semiconductor layer 25, and the transparent electrode 28 and has a uniform protruding amount on the light incident side, it is possible to suppress color mixing between the pixels P and suppress fluctuation in the amount of incident light between the pixels P. In particular, since the through hole is formed from the side opposite to the light incident side, and the second electrode 41, which is a wall-shaped light shielding structure, penetrates both the cap layer 23 and the compound semiconductor layer 25, it is possible to more efficiently suppress charge transfer via the cap layer 23 and the compound semiconductor layer 25. As a result, color mixing between the pixels P is suppressed as described above.

The sidewall protective film 42 and the second insulating film 44 include, for example, an inorganic insulating material. Examples of the inorganic insulating material include silicon nitride (SiN), aluminum oxide (Al₂O₃), silicon oxide (SiO₂), and hafnium oxide (HfO₂). Further, as will be described later in the second embodiment, an insulating film containing phosphorus can be formed on the sidewall protective film 42.

The transparent electrode 28 including a transparent conductive material is formed on a surface of the compound semiconductor layer 25 on the light incident side. Examples of the transparent conductive material include indium-tin oxide (including ITO, Sn-doped In₂O₃, crystalline ITO and amorphous ITO), IFO (F-doped In₂O₃), tin oxide (SnO₂), ATO (Sb-doped SnO₂), FTO (F-doped SnO₂), zinc oxide (including Al doped ZnO, B doped Zno, and Ga doped ZnO), indium oxide-zinc oxide (IZO), titanium oxide (TiO₂), spinel-type oxide, and oxide having a YbFe₂O₄ structure.

A third electrode 45 connecting the pixels P is configured to penetrate the first insulating film 43 and the second insulating film 44. The third electrode 45 electrically connects the transparent electrodes 28 between the pixels P.

The compound semiconductor layer 25 includes, for example, a p-type or n-type compound semiconductor. For example, n-type indium phosphide (InP) can be used for the compound semiconductor layer 25. FIG. 4 illustrates a case where the photoelectric conversion layer 22 is provided in contact with one surface of the compound semiconductor layer 25, but another layer may be interposed between the compound semiconductor layer 25 and the photoelectric conversion layer 22.

Examples of the material of the layer interposed between the compound semiconductor layer 25 and the photoelectric conversion layer 22 include semiconductor materials such as InAlAs, Ge, Si, GaAs, and InP, and it is preferable to select a material having lattice matching between the compound semiconductor layer 25 and the photoelectric conversion layer 22. In the compound semiconductor layer 25, the above-described through hole is provided between the adjacent pixels P. Note that the compound semiconductor layer 25 is, for example, a layer common to the respective pixels P, and is continuously provided between the pixels P.

The photoelectric conversion layer 22 absorbs light having a predetermined wavelength (for example, light having a wavelength in the infrared region) to generate signal charges (electrons or holes), and includes, for example, a group III-V semiconductor. The photoelectric conversion layer 22 is, for example, a layer common to the respective pixels P, and is continuously provided between the pixels P on one surface of the compound semiconductor layer 25. Note that the photoelectric conversion layer 22 may be referred to as a semiconductor substrate.

Examples of the group III-V semiconductor for the photoelectric conversion layer 22 include indium gallium arsenide (InGaAs). The composition of InGaAs is, for example, InxGa (1-x) As (x:0<x≤1). In order to increase the sensitivity in the infrared region, x≥0.4 is preferable. An example of the composition of the photoelectric conversion layer 22 lattice-matched with the compound semiconductor layer 25 including InP is In0.53Ga0.47As.

The photoelectric conversion layer 22 according to the present embodiment includes, for example, an n-type (second conductivity type) group III-V semiconductor, and contains a group IV element or a group VI element to be an n-type impurity. The group IV element is, for example, C (carbon), Si (silicon), Ge (germanium), and Sn (tin), and the group VI element is, for example, S (sulfur), Se (selenium), and Te (tellurium). The concentration of the n-type impurity is, for example, 2×10¹⁷/cm³ or less. The photoelectric conversion layer 22 may include a p-type (first conductivity-type) group III-V semiconductor. In a part of the photoelectric conversion layer 22 on the cap layer 23 side, the first conductivity type region 23A is provided continuously from the cap layer 23.

In the present embodiment, the second conductivity type region 22B penetrating the photoelectric conversion layer 22 in the thickness direction is provided between the adjacent first conductivity type regions 23A. The second conductivity type region 22B extends from the photoelectric conversion layer 22 to the compound semiconductor layer 25 and the cap layer 23, for example. As a result, for example, movement of charges between the pixels P can be prevented.

The second conductivity type region 22B is, for example, an n-type impurity region having a higher concentration than the regions of the other photoelectric conversion layers 22. The impurity concentration of the second conductivity type region 22B is preferably 3 times or more the impurity concentration of the regions of the other photoelectric conversion layers 22. The second conductivity type region 22B includes, for example, a group IV element or a group VI element to be an n-type impurity. The group IV element is, for example, C (carbon), Si (silicon), Ge (germanium), and Sn (tin), and the group VI element is, for example, S (sulfur), Se (selenium), and Te (tellurium). The concentration of the n-type impurity in the second conductivity type region 22B is, for example, 5×10¹⁶/cm³ or more. The width (length in the X direction in FIG. 1) of the second conductivity type region 22B is, for example, 50 nm to 500 nm. The second conductivity type region 22B is provided between the adjacent pixels P, and is provided in, for example, a lattice shape in plan view as described later.

The cap layer 23 is provided between the photoelectric conversion layer 22 and the protective film 24. The cap layer 23 has the first conductivity type region 23A provided for each pixel P, whereby the pixels are electrically separated from each other. The cap layer 23 preferably includes a compound semiconductor having a band gap larger than that of the photoelectric conversion layer 22. For example, when the photoelectric conversion layer 22 including In0. 53Ga0.47As (band gap 0.74 eV) is used, the cap layer 23 can include InP (band gap 1.34 eV) or InAlAs (band gap about 1.56 eV). A semiconductor layer may be interposed between the cap layer 23 and the photoelectric conversion layer 22. For this semiconductor layer, for example, InAlAs, Ge, Si, GaAs, InP, or the like can be used.

The plurality of first conductivity type regions 23A in the cap layer 23 is provided apart from each other for each pixel P. The first conductivity type region 23A is a region to which the signal charge generated in the photoelectric conversion layer 22 moves, and is, for example, a region containing a p-type impurity (p-type impurity region). The first conductivity type region 23A contains p-type impurities such as Zn (zinc), for example. A region in the cap layer 23 other than the first conductivity type region 23A is an n-type impurity region, and contains an n-type impurity such as a group 14 element or a group 16 element, for example, similarly to the compound semiconductor layer 25. The first conductivity type region 23A is provided to extend from, for example, a position in contact with the protective film 24 to a part of the photoelectric conversion layer 22 in the thickness direction thereof. The first conductivity type region 23A may not extend to a part of the photoelectric conversion layer 22, and may be provided up to an interface between the cap layer 23 and the photoelectric conversion layer 22, for example.

The protective film 24 is provided between the cap layer 23 and the sidewall protective film 42A, and includes, for example, an inorganic insulating material. Examples of the inorganic insulating material include silicon nitride (SiN), aluminum oxide (Al₂O₃), silicon oxide (SiO₂), and hafnium oxide (HfO₂). A through hole is provided for each pixel P in the protective film 24, and the first electrode 26 and the second electrode 41 are provided in the through hole.

The first electrode 26 and the second electrode 41 penetrate the protective film 24, and for example, a part thereof is embedded in the multilayer wiring boards L1 and L2. The first electrode 26 and the second electrode 41 are Cu—Cu connected to the wiring of the multilayer wiring board L2. The first electrode 26 is provided for each pixel P, and is electrically connected to the corresponding first conductivity type region 23A and the ROIC of the corresponding multilayer wiring board L3. A voltage for reading signal charges generated in the photoelectric conversion layer 22 is supplied to the first electrode 26. One first electrode 26 may be provided for one pixel P, or a plurality of first electrodes 26 may be provided for one pixel P. Some of the plurality of first electrodes 26 provided for one pixel P may be dummy electrodes (electrodes that do not contribute to charge extraction).

The first electrode 26, the second electrode 41, and the third electrode 45 include, for example, any single substance of titanium (Ti), tungsten (W), titanium nitride (TiN), platinum (Pt), gold (Au), germanium (Ge), palladium (Pd), zinc (Zn), nickel (Ni), and aluminum (Al), or an alloy containing at least one of them. The first electrode 26 may be a single film of such a constituent material, or may be a laminated film obtained by combining two or more kinds.

### [Configuration Example of Layer Direction of Photodetection Element]

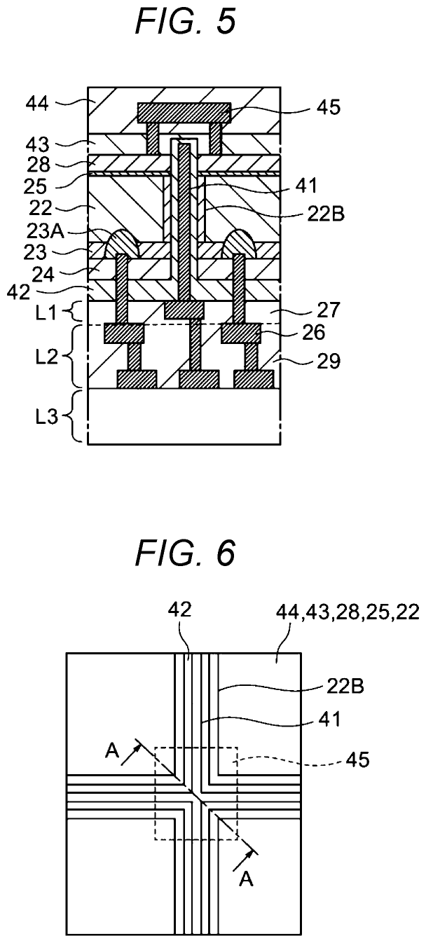

A configuration example in a layer direction of the photodetection element 1a will be described with reference to FIGS. 5 to 12. FIG. 5 is an AA cross-sectional view of FIG. 6. FIG. 6 is a plan view of four adjacent pixels p. FIG. 6 schematically illustrates a plan view of the photoelectric conversion layer 22, the compound semiconductor layer 25, the transparent electrode 28, the first insulating film 43, and the second insulating film 44. As illustrated in FIG. 6, the second conductivity type region 22B and the sidewall protective film 42 are provided between the adjacent pixels P, and are provided in, for example, a lattice shape in plan view. In addition, the second electrode 41 is configured to surround the peripheries of the pixels P between the adjacent pixels P. That is, the second electrodes 41 are provided in a lattice shape in plan view. In other words, the second electrode 41 is configured as a wall-shaped light shielding structure surrounding the peripheries of the pixels P between the adjacent pixels P. Similarly, the sidewall protective film 42 is configured as a wall-shaped protective film surrounding the peripheries of the pixels P between the adjacent pixels P.

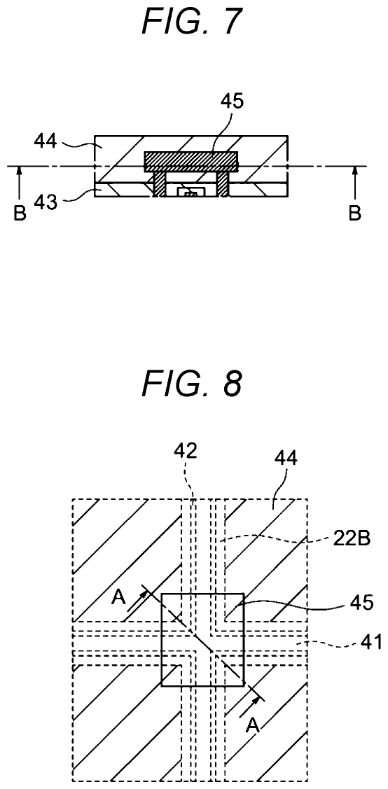

FIG. 7 is an AA cross-sectional view of FIG. 8. A cross section of a partial region of the second insulating film 44 and the first insulating film 43 is illustrated. FIG. 8 is a BB cross-sectional view of FIG. 7. As can be seen from these drawings, the second conductivity type region 22B, the second electrode 41, and the sidewall protective film 42 are not formed in the second insulating film 44, but stop within the first insulating film 43. In this manner, the light receiving surface side is formed while the end on the light receiving surface side of the through hole (groove) is covered with the first insulating film 43. The square head region of the third electrode 45 is configured such that the range covering the pixel P is smaller.

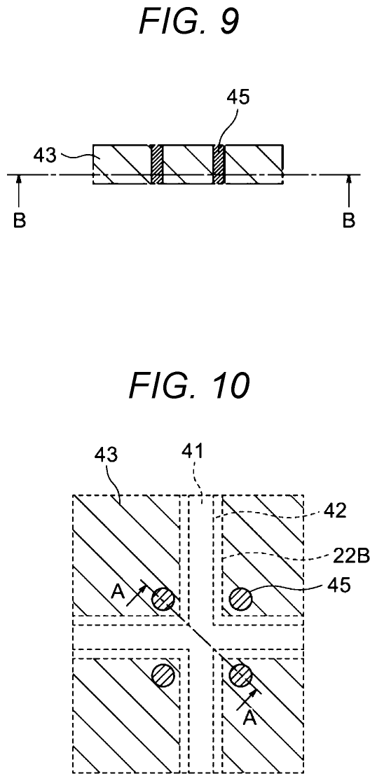

FIG. 9 is an AA cross-sectional view of FIG. 10. A cross section of a partial region of the first insulating film 43 is illustrated. FIG. 10 is a BB cross-sectional view of FIG. 9. As can be seen from these drawings, the wiring portion of the third electrode 45 is formed in a columnar shape. A wiring portion of the third electrode 45 is formed at an adjacent corner portion of the pixel P, but the present invention is not limited thereto. For example, the wiring of the third electrode 45 may be electrically connected to at least one location for each pixel P.

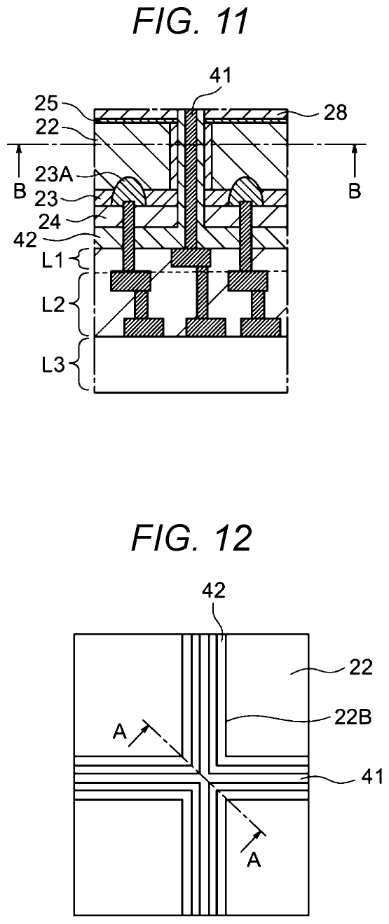

FIG. 11 is an AA cross-sectional view of FIG. 12. A cross section from a part of the transparent electrode 28 to the layer wiring board L3 is illustrated. FIG. 12 is a BB cross-sectional view of FIG. 11. As can be seen from these drawings, the second conductivity type region 22B, the second electrode 41, and the sidewall protective film 42 are provided between the adjacent pixels P. As described above, the second electrode 41 is configured as a wall-shaped light shielding structure penetrating the photoelectric conversion layer 22. Further, the wall-shaped through hole has an opening on the side opposite to the light incident side, and has a closed region on the light incident side.

When the second electrode 41 which is a light shielding structure is formed, so-called burr-like expansion occurs on the side to which the material for forming the light shielding structure is input. The spread of the burr-like shape is a region having a spread larger than the cross-sectional area of the opening, and needs to be removed by etching, for example. That is, so-called burr-like expansion occurs on the opening side of the through hole (groove).

On the other hand, in the second electrode 41 according to the present embodiment, since the through hole (groove) is formed from the side opposite to the incident side, the opening is not formed on the incident light side, so that so-called burr-like expansion does not occur on the incident light side. That is, it is not necessary to delete the end structure of the second electrode 41 on the incident light side by etching, and thus, it is possible to form a configuration according to the end shape of the through hole.

### [Manufacturing Steps of Photodetection Element]

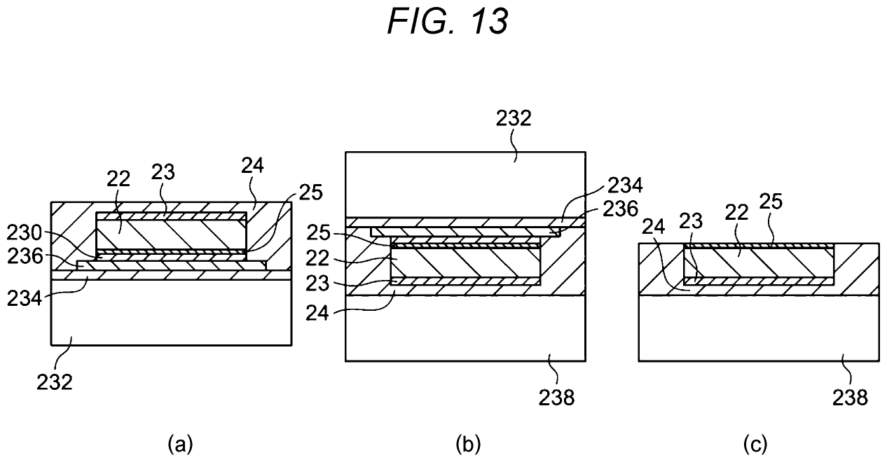

Although the configuration of the present embodiment has been described above, an example of a method for manufacturing the photodetection element 1a will be described below with reference to FIGS. 13 to 16. FIGS. 13 to 16 illustrate manufacturing steps of the photodetection element 1a (see FIG. 4) according to the present embodiment in order of steps.

FIG. 13 is a schematic cross-sectional view for explaining manufacturing steps of the photodetection element 1a (see FIG. 4) according to the present embodiment. As illustrated in FIG. 13(a), the photodetection element 1a is manufactured by forming the cap layer 230 and the adhesive layer 236 for protecting the photoelectric conversion layer 22, and then bonding the photoelectric conversion layer 22 to the temporary substrate 232 with the cap layer 230, the adhesive layer 236, and the insulating layer 234 interposed therebetween. On the cap layer 230, for example, the compound semiconductor layer 25, the photoelectric conversion layer 22, and the cap layer 23 are formed in this order by epitaxial growth. Subsequently, the cap layer 230 is bonded to the large-diameter temporary substrate 232 with the adhesive layer 236 and the insulating layer 234 interposed therebetween. Then, the protective film 24 is laminated. At this time, the adhesive layer 236 and the insulating layer 234 are limited by bonding characteristics. Therefore, it is difficult to freely select a film type, a layer structure, and a film thickness.

As illustrated in FIG. 13(b), a large-diameter temporary substrate 238 is bonded to the protective film 24. Next, as illustrated in FIG. 13(c), the film type, layer structure, and film thickness of the adhesive layer 236 and the insulating layer 234 are limited, and it is difficult to obtain an intended processing selection ratio. Therefore, in the present embodiment, it is removed. That is, the temporary substrate 232, the insulating layer 234, and the adhesive layer 236 are removed. This removal can be performed by mechanical grinding, chemical mechanical polishing (CMP), wet etching, dry etching, or the like. Note that such removal may not be performed in a general manufacturing step. That is, the manufacturing steps (b) to (e) described below are manufacturing steps specific to the present embodiment.

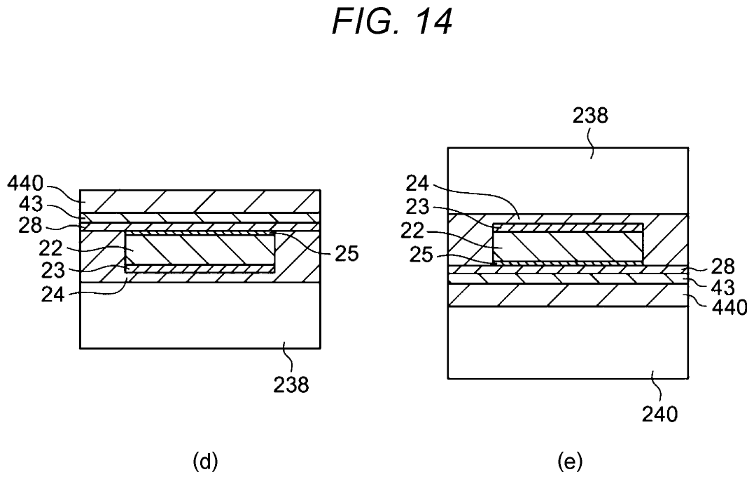

FIG. 14 is a schematic cross-sectional view illustrating steps subsequent to FIG. 13. As illustrated in FIG. 14(d), the transparent electrode 28, the first insulating film 43, and a bonding insulating film 440 are laminated. The bonding insulating film 440 is an insulating film used for bonding. On the other hand, since the first insulating film 43 is not limited in bonding, as described above, it is possible to select a material that satisfies the insulating property and the selection ratio for forming the through hole. That is, the film type, layer structure, and film thickness of the first insulating film 43 can be freely selected according to a structure to be formed.

For the formation of the transparent electrode 28, it is possible to use, for example, physical vapor deposition methods (PVD methods) such as a vacuum vapor deposition method, a reactive vapor deposition method, various sputtering methods, an electron beam vapor deposition method, and an ion plating method, various chemical vapor deposition methods (CVD methods) including a pyrosol method, a method for thermally decomposing an organometallic compound, a spray method, a dip method, and an MOCVD method, an electroless plating method, and an electrolytic plating method. The first insulating film 43 and the bonding insulating film 440 can be formed by, for example, a CVD method. Then, as illustrated in FIG. 14(e), the temporary substrate 240 is bonded to the bonding insulating film 440.

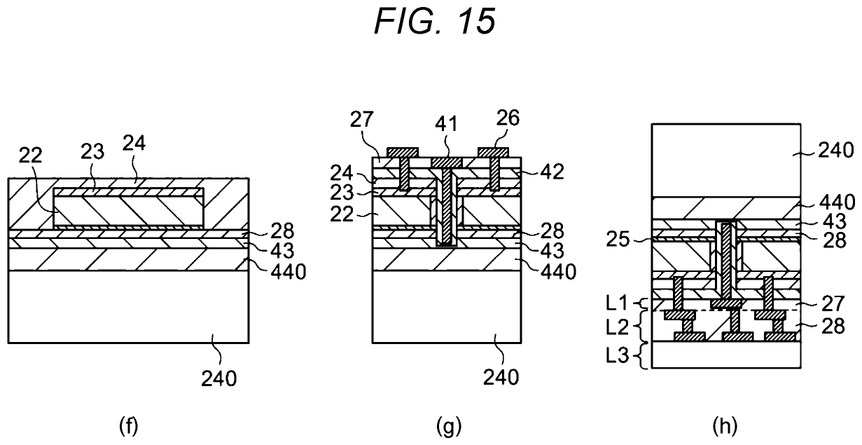

FIG. 15 is a schematic cross-sectional view illustrating steps subsequent to FIG. 14. As illustrated in FIG. 15(f), the temporary substrate 238 is removed. This removal can be performed by mechanical grinding, chemical mechanical polishing (CMP), wet etching, dry etching, or the like.

As illustrated in FIG. 15(g), after the cap layer 23 and the protective film 24 are formed on one surface of the photoelectric conversion layer 22, and the compound semiconductor layer 25, the transparent electrode 28, and the first insulating film 43 are formed on the other surface, a through hole constituting the second electrode 41 is formed. At this time, since the first insulating film 43 functions as a stop layer, the through hole can be made to have a uniform depth. As a result, the end surface of the through hole on the light receiving side can be uniformly configured.

In addition, the second conductivity type region 22B is formed around the through hole. The second electrode 41 is formed after the sidewall protective film 42 is formed. Further, after the insulating film 27 is formed, a through hole for the first electrode 26 is formed. Subsequently, for example, p-type impurities (for example, zinc (Zn) ) are vapor-phase diffused. As a result, the cap layer 23 having the first conductivity type region 23A is formed for each pixel P. Thereafter, the first electrode 26 is formed. Then, as illustrated in FIG. 15(h), the layer wiring boards L1, L2, and L3 are configured. As described above, since the layer wiring boards L1, L2, and L3 are configured after the second conductivity type region 22B and the first conductivity type region 23A are formed, thermal deterioration of the layer wiring boards L1, L2, and L3 is suppressed.

Note that examples of a method for forming the second conductivity type region 22B include a gas phase diffusion method and a solid phase diffusion method of an impurity having the second conductivity type. When the second conductivity type is p-type, zinc (Zn) and magnesium (Mg) can be exemplified as impurities. In addition, zinc (Zn) or magnesium (Mg) may be introduced by an ion implantation method.

The formation of various semiconductor layers according to the present embodiment can be performed on the basis of, for example, metalorganic chemical vapor deposition method (MOCVD method, MetalOrganic-ChemicalVaporDeposition method, MOVPE method, MetalOrganic-VaporPhaseEpitaxy method), molecular beam epitaxy method (MBE method), hydride vapor phase epitaxy method (HVPE method) in which halogen contributes to transport or reaction, atomic layer deposition method (ALD method, AtomicLayerDeposition method), migration enhanced epitaxy method (MEE method, Migration-EnhancedEpitaxy method), plasma assisted physical vapor deposition (PPD method), or the like. Note that, in the present embodiment, such a film forming method may be referred to as epitaxial growth.

In addition, the recess and the groove according to the present embodiment can be formed on the basis of a wet etching method or a dry etching method. Alternatively, the groove can be formed at the same time when the recess is filled with a light shielding material (for example, an electrode). Note that the manufacturing step of each layer according to the present embodiment is an example, and is not limited thereto.

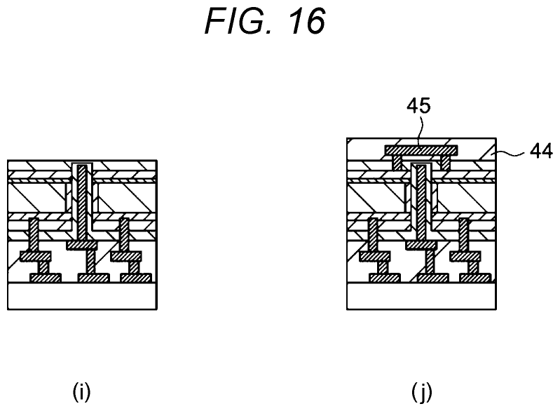

FIG. 16 is a schematic cross-sectional view illustrating steps subsequent to FIG. 15. As illustrated in FIG. 16(i), the temporary substrate 240 and the bonding insulating film 440 are removed. This removal can be performed by mechanical grinding, chemical mechanical polishing (CMP), wet etching, dry etching, or the like. As described above, when the unnecessary layer on the light receiving surface side is removed, the ends on the light receiving side of the second electrode 41 and the sidewall protective film 42 are covered with the first insulating film 43 and are not exposed. As a result, deterioration of the second electrode 41 and the sidewall protective film 42 is suppressed.

As illustrated in FIG. 16(j), the second insulating film 44 is formed after the third electrode 45 is formed in the through hole of the first insulating film 43. The second insulating film 44 can be formed by, for example, a CVD method. At this time, since the photoelectric conversion layer 22 and the compound semiconductor layer 25 are covered and continuously protected by the transparent electrode 28 and the first insulating film 43, process damage to the compound layer does not occur, and characteristic deterioration is suppressed.

As described above, after the adhesive layer 236 and the insulating layer 234 are removed, the first insulating film 43 is re-formed using a material satisfying the insulating property and the selection ratio when the through hole is formed. As a result, when the through hole is formed on the incident light side of the photoelectric conversion layer 22, variation in the protruding amount of the through hole can be suppressed. As a result, color mixing for each pixel P can be suppressed, and the amount of incident light can be made uniform. Further, after the second conductivity type region 22B and the first conductivity type region 23A are formed, the layer wiring boards L1, L2, and L3 are sequentially formed. Therefore, it is possible to suppress the influence on the layer wiring boards L1, L2, and L3 due to the heat treatment of the second conductivity type region 22B and the first conductivity type region 23A.

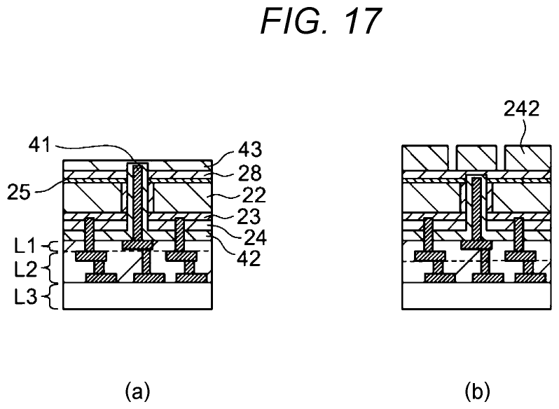

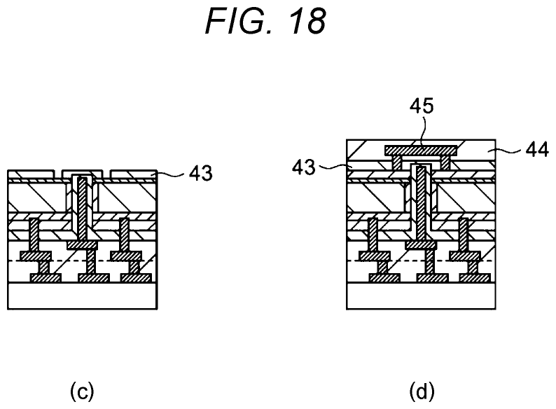

FIGS. 17 and 18 illustrate steps of manufacturing the third electrode 45 of the photodetection element 1a (see FIG. 4) according to the present embodiment in order of steps. FIG. 17(a) is a diagram illustrating a state equivalent to that of FIG. 16(i). As illustrated in FIG. 17(b), a resist mask 242 is formed.

FIG. 18 is a schematic cross-sectional view illustrating steps subsequent to FIG. 17. As illustrated in FIG. 18(c), the first insulating film 43 is etched through the resist mask 242 to form a wiring hole of the third electrode 45. Subsequently, as illustrated in FIG. 18(d), after the third electrode 45 is formed in the wiring hole of the third electrode 45, the second insulating film 44 is formed by, for example, the CVD method.

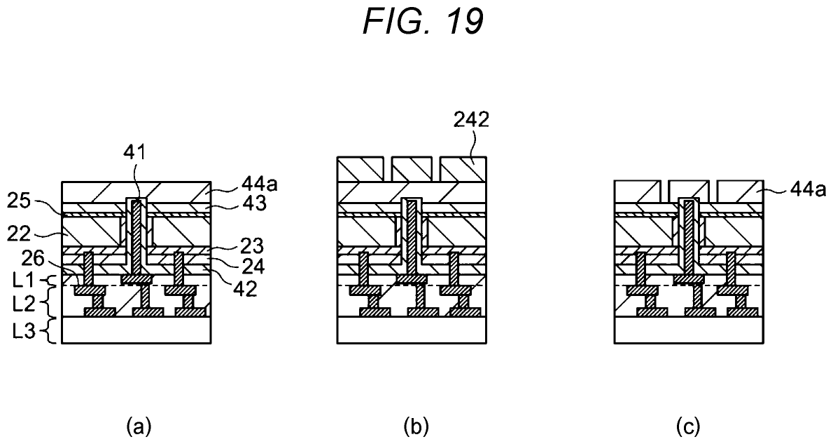

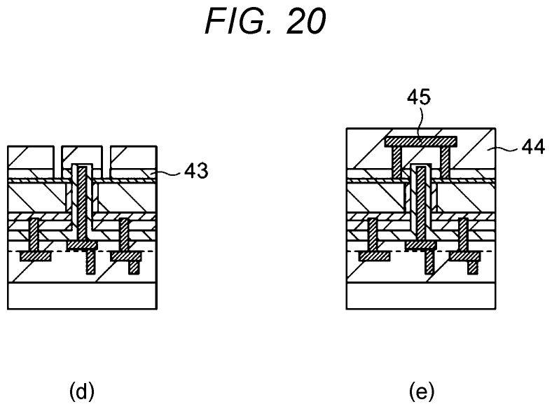

FIGS. 19 and 20 illustrate another manufacturing step of the third electrode 45 in the photodetection element 1a (see FIG. 4) according to the present embodiment in order of steps. In FIG. 19(a), a second insulating film 44a is formed together with the first insulating film 43, and the through hole is stopped by the second insulating film 44a.

As illustrated in FIG. 19(b), the resist mask 242 is formed on the upper surface of the second insulating film 44a. Then, as illustrated in FIG. 19(c), the wiring hole of the third electrode 45 is formed in the second insulating film 44a by etching the second insulating film 44a.

FIG. 20 is a schematic cross-sectional view illustrating steps subsequent to FIG. 19. As illustrated in FIG. 20(d), the first insulating film 43 is etched via the second insulating film 44a to form a wiring hole of the third electrode 45. Subsequently, as illustrated in FIG. 18(e), after the third electrode 45 is formed in the wiring hole of the third electrode 45, the second insulating film 44 is further formed by, for example, a CVD method.

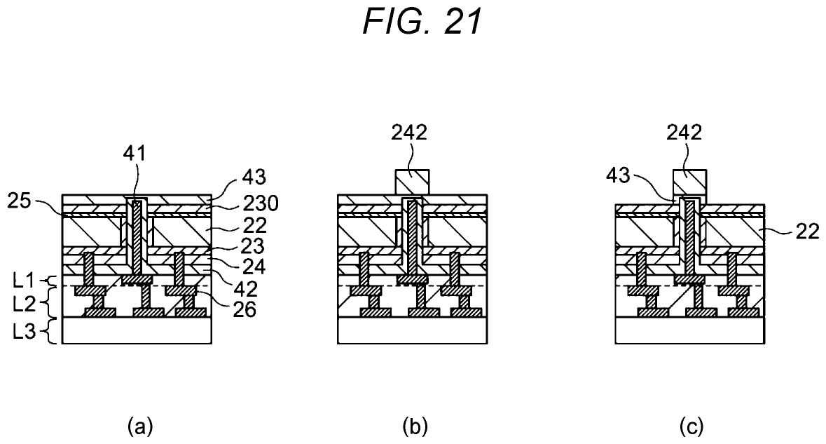

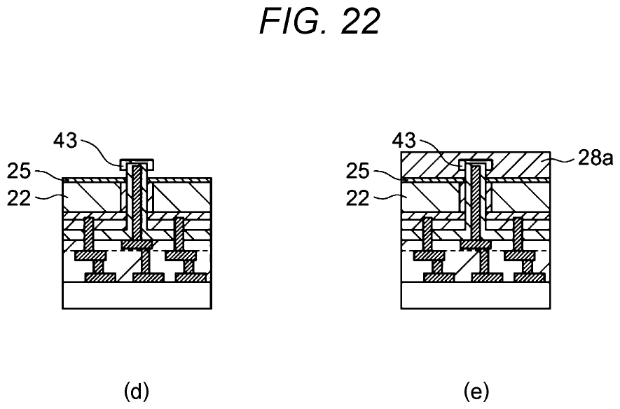

FIGS. 21 and 22 illustrate other manufacturing steps of the photodetection element 1a (see FIG. 4) according to the present embodiment in order of steps.

The steps are different from the steps in FIGS. 13 to 16 in that the cap layer 230 is left in the step of removing the insulating layer in FIG. 13(b) to 13(c). In addition, the present invention is different in that the transparent electrode 28 is formed on a surface of the compound semiconductor layer 25 on the incident side.

FIG. 21(a) illustrates a state in which the cap layer 230 is left and the processing proceeds without forming the transparent electrode 28 until FIG. 15(h). That is, the cap layer 230 is laminated instead of the transparent electrode 28.

In FIG. 21(b), the cap-shaped resist mask 242 is formed on the upper surface of the first insulating film 43. In FIG. 21(c), the first insulating film 43 is removed. At this time, in a case where the first insulating film 43 is removed by dry etching (Dry Etch), that is, anisotropic etching, adverse effects on dimensions are suppressed, and damage to the photoelectric conversion layer 22 and the compound semiconductor layer 25 can be suppressed by reducing the amount of over etching (Over Etch). On the other hand, in a case where the first insulating film 43 is removed by wet etching (Wet Etch), that is, isotropic etching, damage to the photoelectric conversion layer 22 and the compound semiconductor layer 25 can be suppressed, and by reducing the over etching amount, lateral spread is reduced, and adverse effects on dimensions are suppressed.

FIG. 22 is a schematic cross-sectional view illustrating steps subsequent to FIG. 21. Further, in FIG. 22(d), the cap layer 230 is removed. Then, in FIG. 22(e), a transparent electrode 28a is formed. Then, similarly FIG. 16(j), the second insulating film 44 and the third electrode 44 are formed on the transparent electrode 28a.

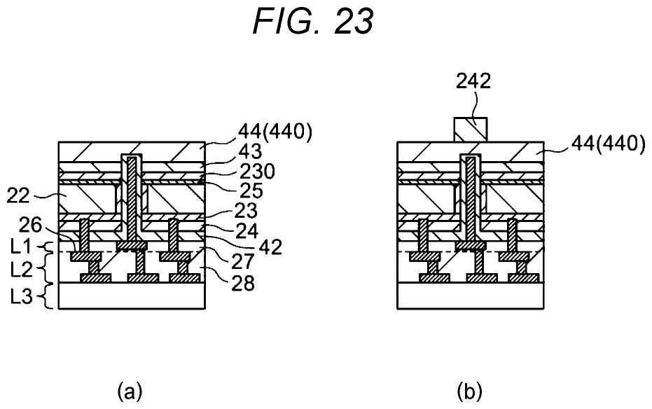

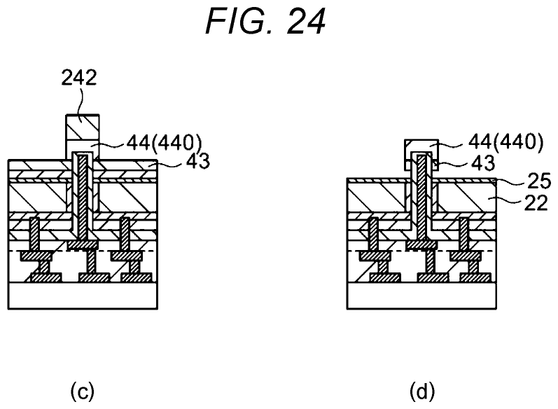

FIGS. 23 and 24 illustrate still other manufacturing steps of the photodetection element 1a (see FIG. 4) according to the present embodiment in order of steps. The steps are different from the steps in FIGS. 13 to 16 in that the cap layer 230 is left in the step of removing the insulating layer in FIG. 13(b) to 13(c). Further, the steps are different in that the bonding insulating film 440 is left, a through hole is formed up to the bonding insulating film 440, and the transparent electrode 28 is formed on the surface of the compound semiconductor layer 25 on the incident side. Alternatively, the bonding insulating film 440 may be removed, and the second insulating film 44 having a high selection ratio may be formed on the first insulating film 43. When the processing selection ratio between the first insulating film 43 and the second insulating film 44 is set to be high, the first insulating film 43 can be configured to be thinner.

FIG. 23(a) illustrates a state in which the cap layer 230 and the bonding insulating film 440 are left and the processing proceeds without forming the transparent electrode 28 until FIG. 15(h). That is, the cap layer 230 is laminated instead of the transparent electrode 28, and the through hole is stopped by the bonding insulating film 440. In FIG. 23(b), the resist mask 242 is formed on the upper surface of the bonding insulating film 440.

FIG. 24 is a schematic cross-sectional view illustrating steps subsequent to FIG. 23. In FIG. 24(c), the bonding insulating film 440 is removed. At this time, if the processing selection ratio of the first insulating film 43 and the bonding insulating film 440 is set to be high, the first insulating film 43 can be made thinner, and the damage can be reduced in the case of Dry and the adverse effect on the dimension can be reduced in the case of Wet by reducing the processing amount.

Further, in FIG. 24(d), the first insulating film 43 and the cap layer 230 are removed. Then, the transparent electrode 28a is formed similarly FIG. 21(e), and the second insulating film 44 is formed on the transparent electrode 28a similarly FIG. 16(j).

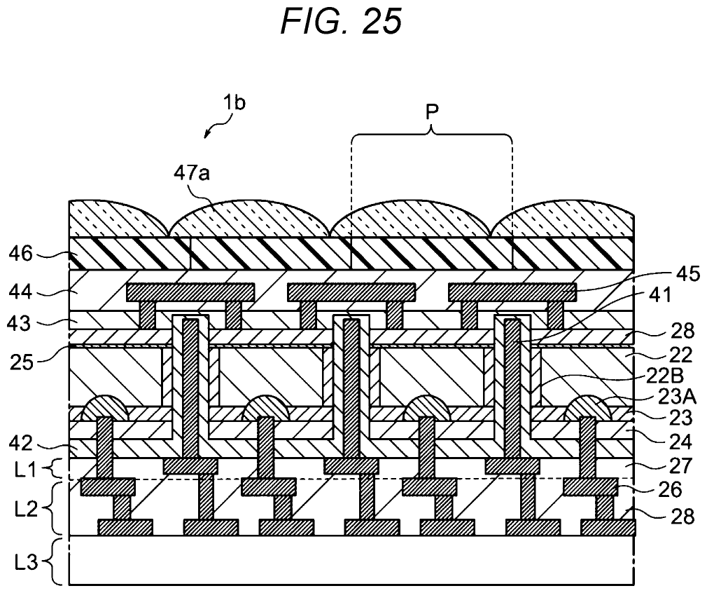

FIG. 25 is a diagram illustrating a configuration example of an optical element configured in a peripheral region of the photodetection element 1a. The configuration example is different from the optical element illustrated in FIG. 4 in that the on-chip lens 47 is eccentric with respect to the color filter 46. As a result, even in a case where the incident light travels to the peripheral region from an oblique direction with respect to the center region, a decrease in the light receiving efficiency can be suppressed.

Note that the insulating layer according to the present embodiment can be formed on the basis of various physical vapor deposition methods (PVD methods) or chemical vapor deposition methods (CVD methods). Furthermore, the light shielding material layer according to the present embodiment can be formed on the basis of various PVD methods. Examples of the film forming method using the principle of the PVD method include a vacuum vapor deposition method using resistance heating or high frequency heating, an electron beam (EB) vapor deposition method, various sputtering methods (magnetron sputtering method, RF-DC coupled bias sputtering method, ECR sputtering method, counter target sputtering method, and high frequency sputtering method), an ion plating method, a laser ablation method, a molecular beam epitaxy method, and a laser transfer method. Further, examples of the CVD method include a plasma CVD method, a thermal CVD method, an organic metal (MO) CVD method, and a photo CVD method.

As described above, according to the present embodiment, the second electrode 41, which is a light shielding structure penetrating the photoelectric conversion layer 22, the cap layer 23, and the compound semiconductor layer 25, is configured between the pixels P. As a result, color mixing through the photoelectric conversion layer 22, the cap layer 23, and the compound semiconductor layer 25 between the pixels P can be suppressed. In addition, even when the through hole penetrating the compound semiconductor layer 25 and constituting the second electrode 41 as a light shielding structure is formed from the opposite side to the incident side, the length of the through hole (groove) can be adjusted with higher accuracy by forming the first insulating film 43, the second insulating film 44, and the like having a high stop processing selection ratio on the incident side of the photoelectric conversion layer 22.

### Second Embodiment

An electronic device according to a second embodiment is different from the electronic device according to the first embodiment in that an insulating film containing phosphorus is formed on a material of a protective film of a through hole in which a second electrode 41 which is a light shielding structure in a photodetection element is embedded. Hereinafter, differences from the electronic device according to the first embodiment will be described.

### [Configuration Example of Photodetection Element]

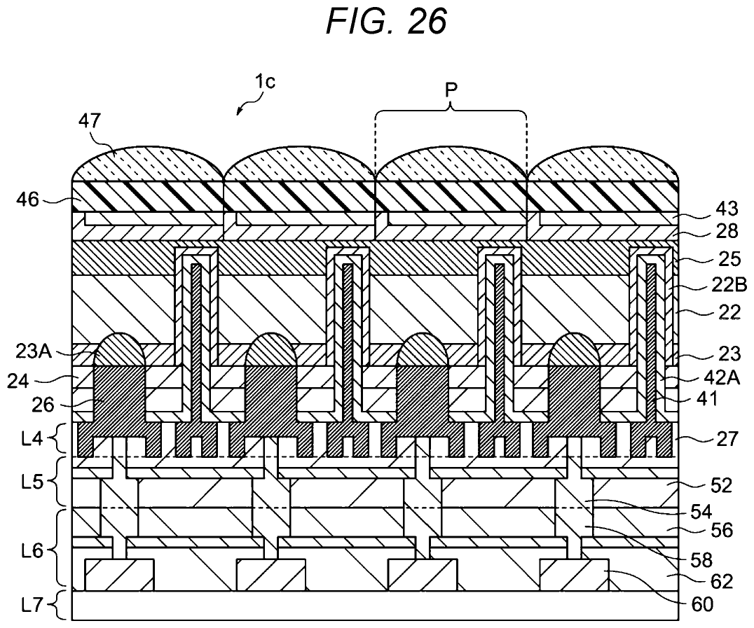

FIG. 26 is a diagram illustrating an example of a cross-sectional view of the photodetection element according to the second embodiment. The photodetection element 1c is applied to, for example, an infrared sensor or the like, and includes a plurality of pixels P (see FIG. 2) arranged two-dimensionally. Functional components equivalent to those of the photodetection element 1a according to the first embodiment are denoted by the same reference numerals, and the description thereof may be omitted. In addition, even in the configuration denoted with the same number, the shape, the material, the dimension, the manufacturing method, the manufacturing order, and the like can be changed from those of the photodetection element 1a according to the first embodiment.

### [Sidewall Protective Film]

The photodetection element 1c includes a photoelectric conversion layer 22, and a cap layer 23, a protective film 24, and a sidewall protective film 42A are sequentially formed on one surface of the photoelectric conversion layer 22. The sidewall protective film 42A is formed continuously from the sidewall of the groove to one surface of the protective film 24. In addition, the compound semiconductor layer 25 and the transparent electrode 28 are sequentially formed on the other surface of the photoelectric conversion layer 22.

The sidewall protective film 42a has a film thickness of, for example, 2 to 20 nm, and is doped with phosphorus (P). The doping concentration of phosphorus is, for example, 1e^{20˜22} cm⁻³.

### [Influence on Interface State]

The photoelectric conversion layer 22, the cap layer 23, and the compound semiconductor layer 25 are formed on the sidewall of the through hole in which the second electrode 41 is embedded. Examples of the group III-V semiconductor for the photoelectric conversion layer 22 include indium gallium arsenide (InGaAs). For example, n-type indium phosphide (InP) can be used for the compound semiconductor layer 25. The cap layer 23 preferably includes a compound semiconductor having a band gap larger than that of the photoelectric conversion layer 22. For example, when the photoelectric conversion layer 22 including In0. 53Ga0.47As (band gap 0.74 eV) is used, the cap layer 23 can include InP (band gap 1.34 eV) or InAlAs (band gap about 1.56 eV). A semiconductor layer may be interposed between the cap layer 23 and the photoelectric conversion layer 22. For this semiconductor layer, for example, InAlAs, Ge, Si, GaAs, InP, or the like can be used.

As described above, the photoelectric conversion layer 22 includes indium gallium arsenide (InGaAs) as a semiconductor, for example. Meanwhile, n-type indium phosphide (InP) is used for the compound semiconductor layer 25. Further, when the photoelectric conversion layer 22 including In0.53Ga0.47As (band gap 0.74 eV) is used for the cap layer 23, the cap layer 23 includes InP (band gap 1.34 eV) or InAlAs (band gap about 1.56 eV).

Therefore, when the sidewall protective film includes silicon oxide (SiO₂) which is not doped with phosphorus (P), a dark current may be deteriorated due to an influence of an interface state with silicon oxide (SiO₂) in the case of using indium gallium arsenide (InGaAs). That is, in a case where indium gallium arsenide (InGaAs) is used for any of the photoelectric conversion layer 22, the cap layer 23, and the compound semiconductor layer 25, the dark current may be deteriorated, that is, the dark current may be further increased due to the influence of the interface state with silicon oxide (SiO₂) doped with no phosphorus (P).

On the other hand, even if the influence of the interface state on indium gallium arsenide (InGaAs) is suppressed, the influence of the interface state on indium phosphide (InP) may occur. For example, indium gallium arsenide (InGaAs) is used for the photoelectric conversion layer 22 and the cap layer 23, and indium phosphide (InP) is used for the compound semiconductor layer 25. Conversely, for example, indium phosphide (InP) is used for the photoelectric conversion layer 22 and the cap layer 23, and indium gallium arsenide (InGaAs) is used for the compound semiconductor layer 25. In such a case, if the sidewall protective film includes silicon oxide (SiO₂), silicon nitride (SiN), aluminum oxide (Al₂O₃), hafnium oxide (HfO₂), or the like, which is not doped with phosphorus (P), an intended interface state cannot be formed for both the indium gallium arsenide (InGaAs) layer and the indium phosphide (InP) layer, and a dark current may be deteriorated, that is, a dark current may be further increased.

Therefore, in the present embodiment, as described above, the sidewall protective film 42A includes an insulating film doped with phosphorus (P). The sidewall protective film 42A includes, for example, any of phosphorated quartz nitrite (PSG: Phosphosilicate Glass), phosphorus nitride (PxNy), and phosphorus oxide (PxOy).

As a result, an intended interface state can be formed for both indium gallium arsenide (InGaAs) and indium phosphide (InP), and the dark current can be more efficiently suppressed.

As illustrated in FIG. 26, layer wiring boards L4, L5, L6, and L7 are sequentially formed on one surface of the sidewall protective film 42A. Similarly to the above, the first conductivity type region 23A is provided for each pixel P in the photoelectric conversion layer 22 and the cap layer 23. The photodetection element 1c includes a first electrode 26 penetrating the protective film 24 and the sidewall protective film 42A, and the first conductivity type region 23A and the ROIC (Readout Integrated Circuit) of the multilayer wiring board L7 are electrically connected by the first electrode 26 by Cu—Cu bonding. Each of the layer wiring boards L4, L5, L6, and L7 includes insulating films 27, 52, 56, and 62. Wiring, the first electrode 26, and the second electrode 41 are formed on the insulating film 27.

As described above, the compound semiconductor layer 25, the transparent electrode 28, the first insulating film 43, the color filter 46 (see FIG. 3), and the on-chip lens 47 are provided in this order on the other surface of the photoelectric conversion layer 22. The compound semiconductor layer 25 is continuously formed for each pixel P, for example.

A through hole (groove) penetrating the photoelectric conversion layer 22, the cap layer 23, and the protective film 24 and stopping at the compound semiconductor layer 25 is provided between the adjacent pixels P. The sidewall protective film 42A and the second electrode 41 as a light shielding structure are embedded in the through hole. In addition, the second electrode 41 penetrates the protective film 24 and the sidewall protective film 42A, and is connected to a read out integrated circuit (ROIC) of the multilayer wiring board L7 via wiring portions 54, 58, 60, and the like by Cu—Cu. The second electrode 41 is provided between the pixels P adjacent to each other, and is provided in, for example, a lattice shape in plan view as described later. In this manner, color mixing between the pixels P is suppressed by forming the light shielding structure that shields the photoelectric conversion layer 22, the cap layer 23, and the compound semiconductor layer 25 between the pixels P.

The insulating films 27, 52, 56, and 62 include, for example, an inorganic insulating material. Examples of the inorganic insulating material include silicon nitride (SiN), aluminum oxide (Al₂O₃), silicon oxide (SiO₂), and hafnium oxide (HfO₂).

The transparent electrode 28 including a transparent conductive material is formed on a surface of the compound semiconductor layer 25 on the light incident side. The second conductivity type region 22B is, for example, an n-type impurity region having a higher concentration than the regions of the other photoelectric conversion layers 22. The impurity concentration of the second conductivity type region 22B is preferably 3 times or more the impurity concentration of the regions of the other photoelectric conversion layers 22. The second conductivity type region 22B includes, for example, a group IV element or a group VI element to be an n-type impurity. The second conductivity type region 22B is provided between the adjacent pixels P, and is provided in, for example, a lattice shape in plan view as described later.

The plurality of first conductivity type regions 23A in the cap layer 23 is provided apart from each other for each pixel P. The first conductivity type region 23A is a region to which the signal charge generated in the photoelectric conversion layer 22 moves, and is, for example, a region containing a p-type impurity (p-type impurity region). The first conductivity type region 23A is provided to extend from, for example, a position in contact with the protective film 24 to a part of the photoelectric conversion layer 22 in the thickness direction thereof. The first conductivity type region 23A may not extend to a part of the photoelectric conversion layer 22, and may be provided up to an interface between the cap layer 23 and the photoelectric conversion layer 22, for example.

The protective film 24 is provided between the cap layer 23 and the sidewall protective film 42A, and includes, for example, an inorganic insulating material. Examples of the inorganic insulating material include silicon nitride (SiN), aluminum oxide (Al₂O₃), silicon oxide (SiO₂), and hafnium oxide (HfO₂). A through hole is provided for each pixel P in the protective film 24, and the first electrode 26 and the second electrode 41 are provided in the through hole. Note that the protective film 24 according to the embodiment is configured as two layers, but may be configured as one layer.

Similarly to the above, the first electrode 26 and the second electrode 41 include, for example, any single substance of titanium (Ti), tungsten (W), titanium nitride (TiN), platinum (Pt), gold (Au), germanium (Ge), palladium (Pd), zinc (Zn), nickel (Ni), and aluminum (Al), or an alloy containing at least one of them.

[Planar Arrangement Example of Second Electrode 41 and Sidewall Protective Film 42a]

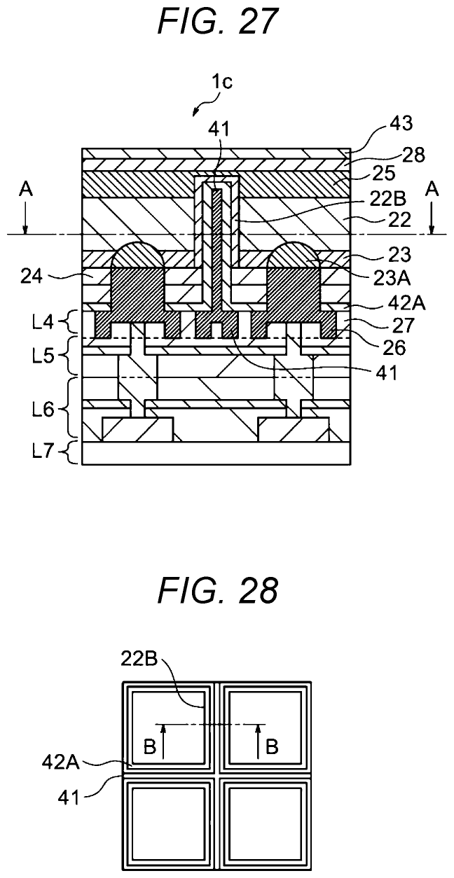

FIG. 27 is a BB cross-sectional view of FIG. 28. FIG. 28 is a BB cross-sectional view of FIG. 27. FIG. 28 is a cross-sectional view of four adjacent pixels p. As illustrated in FIG. 27, the second conductivity type region 22B and the sidewall protective film 42A are provided between the adjacent pixels P, and are provided in, for example, a lattice shape in plan view. In addition, the second electrode 41 is configured to surround the peripheries of the pixels P between the adjacent pixels P. That is, the second electrodes 41 are provided in a lattice shape in plan view.

### [Manufacturing Steps of Photodetection Element]

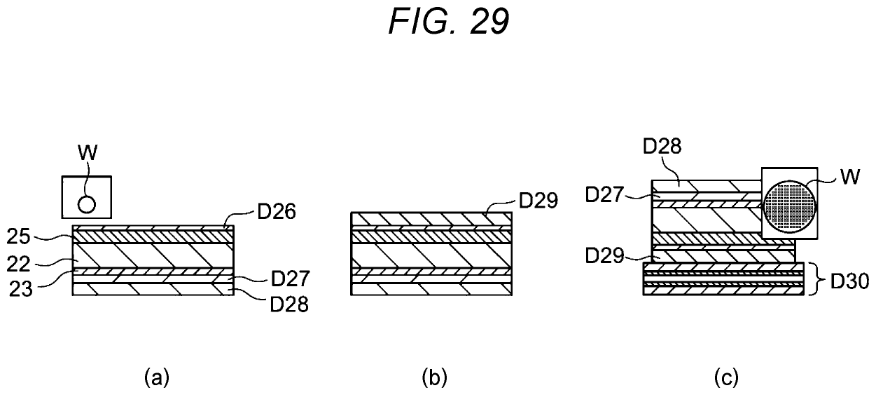

Although the configuration of the present embodiment has been described above, an example of a method for manufacturing the photodetection element 1c will be described below with reference to FIGS. 29 to 34. FIGS. 29 to 34 illustrate manufacturing steps of the photodetection element 1c (see FIG. 26) according to the present embodiment in order of steps.

FIG. 29 is a schematic cross-sectional view for explaining manufacturing steps of the photodetection element 1c (see FIG. 26) according to the second embodiment. As illustrated in FIG. 29(a), in the photodetection element 1c, the cap layer 23, the photoelectric conversion layer 22, the compound semiconductor layer 25, and a temporary film formation D26 are sequentially formed by epitaxial growth with respect to temporary film formation D28 and D27. These are formed, for example, in a 3 inch wafer state (W).

Each of the temporary film formations D28 and D27 is formed using, for example, indium phosphide (InP). The temporary film formation D26 includes indium gallium arsenide (InGaAs), for example.

As illustrated in FIG. 29(b), a bonding film D29 is further formed on the temporary film formation D26. The bonding film D29 includes, for example, tetraethoxysilane (TEOS) or the like.

As illustrated in FIG. 29(C), a chip D30 is further bonded to the bonding film D29. The chip D30 includes a silicon wafer or the like. These are formed in the illustrated wafer state (W) as patterning layers on the chip D30.

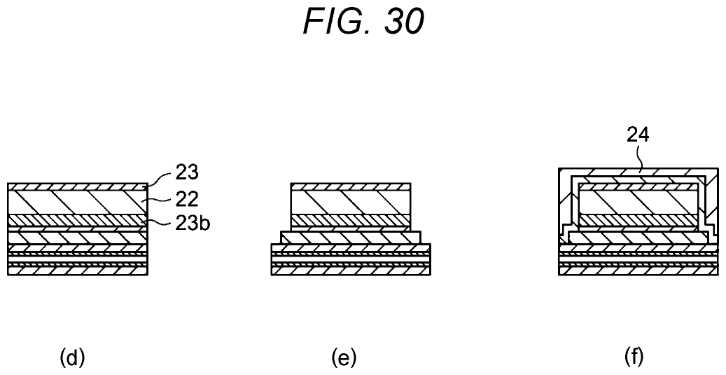

FIG. 30 is a schematic cross-sectional view illustrating steps subsequent to FIG. 29. As illustrated in FIG. 29(d), the temporary film formations D28 and D27 are removed by etching. Subsequently, as illustrated in FIG. 29(e), the cap layer 23, the photoelectric conversion layer 22, the compound semiconductor layer 25, the temporary substrate D26, and the bonding film D29 on the chip D30 are patterned by etching. Then, as illustrated in FIG. 29(f), the protective film 24 is formed by epitaxial growth.

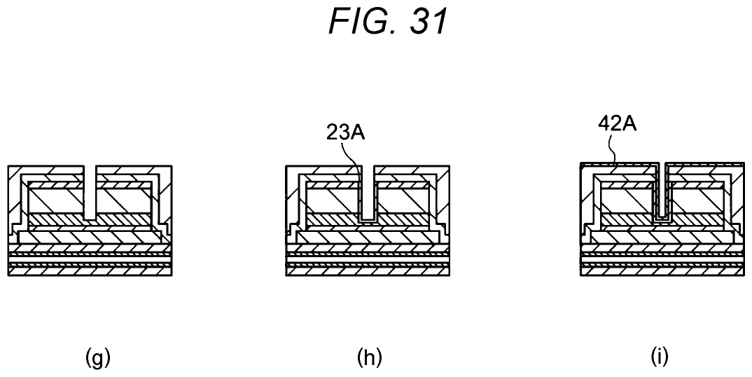

FIG. 31 is a schematic cross-sectional view illustrating steps subsequent to FIG. 30. As illustrated in FIG. 31(g), a through hole penetrating the protective film 24, the cap layer 23, and the photoelectric conversion layer 22 and stopping at the compound semiconductor layer 25 is formed. The through hole is formed by, for example, a photolithography technique and an etching technique.

Subsequently, as illustrated in FIG. 31(h), for example, a silicon oxide film (SiO₂) is formed in the through hole, and then heat treatment is performed for a long time. As a result, the n-type impurity spreads around the through hole, and the second conductivity type region 22B having a desired width is formed. The second conductivity type region 22B may be formed by gas layer diffusion or ion implantation in addition to the above-described solid-layer diffusion method. Subsequently, as illustrated in FIG. 31(i), the sidewall protective film 42A is formed by using, for example, atomic layer deposition (ALD). In addition, a plurality of layered structures may be formed by forming a non-phosphorus-doped insulating film on the phosphorus-doped film. At this time, the phosphorus-doped film on the flat portion may be peeled off.

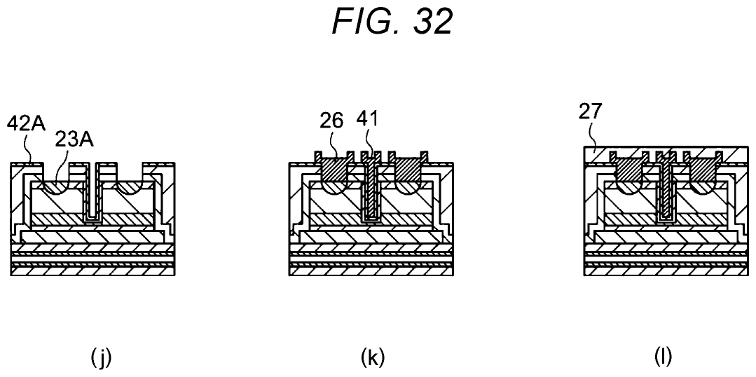

FIG. 32 is a schematic cross-sectional view illustrating steps subsequent to FIG. 31. As illustrated in FIG. 32(j), a through hole penetrating the sidewall protective film 42A and the protective film 24 and stopping at the surface of the cap layer 23 is formed. The through hole is formed by, for example, a photolithography technique and an etching technique. Then, p-type impurities (for example, zinc (Zn)) are vapor-phase diffused in the bottom region of the through hole. Thus, the cap layer 23 having the first conductivity type region 23A is formed. Subsequently, as illustrated in FIG. 32(k), the first electrode 26 and the second electrode 41 are formed in the through hole. Then, as illustrated in FIG. 32(l), the insulating film 27 is further formed by epitaxial growth.

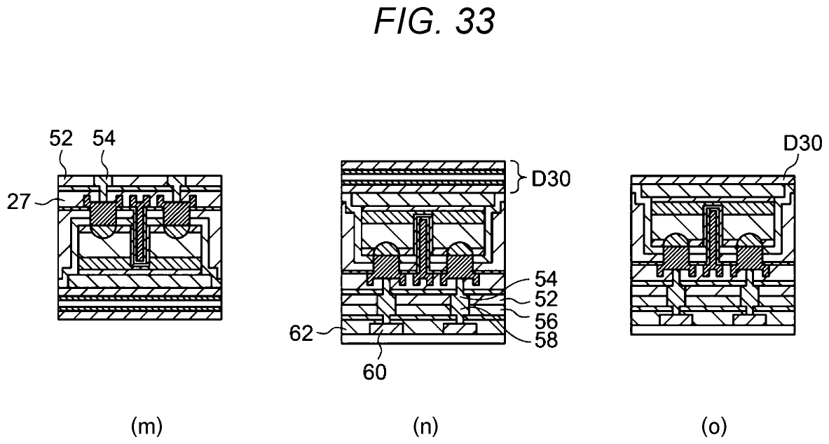

FIG. 33 is a schematic cross-sectional view illustrating steps subsequent to FIG. 32. As illustrated in FIG. 33(m), the insulating film 54 is formed by epitaxial growth. For example, the wiring portion 54 is formed in a through hole formed by a photolithography technique and an etching technique.

Subsequently, as illustrated in FIG. 33(n), the insulating film 56 is formed by epitaxial growth. Then, for example, the wiring portion 58 is formed in a through hole formed by a photolithography technique and an etching technique. Subsequently, the insulating film 62 is formed by epitaxial growth. For example, a wiring portion 60 is formed in a through hole formed by a photolithography technique and an etching technique, and a read out integrated circuit (ROIC) of the multilayer wiring board and the wiring portion 60 are Cu—Cu bonded and electrically connected. Next, as illustrated in FIG. 33(o), the predetermined phase of the chip D30 is etched.

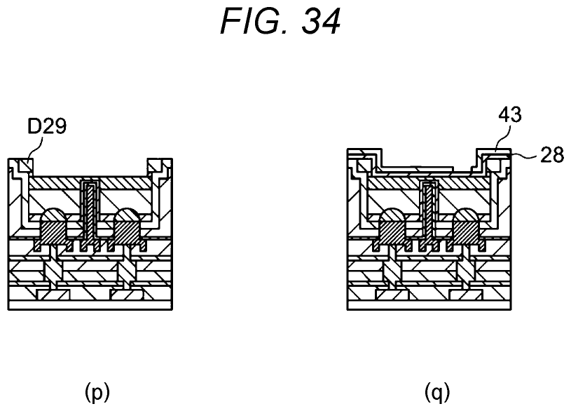

FIG. 34 is a schematic cross-sectional view illustrating steps subsequent to FIG. 33. As illustrated in FIG. 34(p), the remaining phase of the chip D30 is removed by a photolithography technique and an etching technique, and the bonding film D29 is patterned into a predetermined shape.

As illustrated in FIG. 34(q), the transparent electrode 28 is formed in the formed through hole. For example, for the formation of the transparent electrode 28, it is possible to use physical vapor deposition methods (PVD methods) such as a vacuum vapor deposition method, a reactive vapor deposition method, various sputtering methods, an electron beam vapor deposition method, and an ion plating method, various chemical vapor deposition methods (CVD methods) including a pyrosol method, a method for thermally decomposing an organometallic compound, a spray method, a dip method, and an MOCVD method, an electroless plating method, and an electrolytic plating method. Then, after the first insulating film 43 is formed by epitaxial growth, a predetermined region of the first insulating film 43 is removed by a photolithography technique and an etching technique.

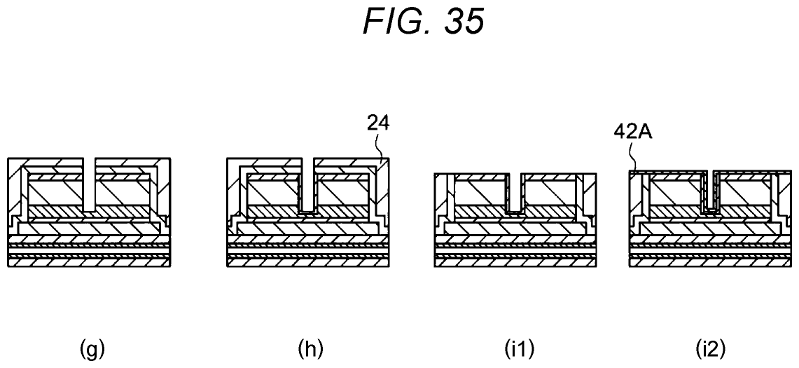

In FIG. 35, the manufacturing steps of the sidewall protective film 42A are different from the manufacturing steps of FIGS. 29 to 34. As illustrated in FIG. 35(i1), the protective film 24 on the cap layer 23 is removed. Then, as illustrated in FIG. 35(i2), the sidewall protective film 42A is formed on the cap layer 23 using, for example, atomic layer deposition (ALD).

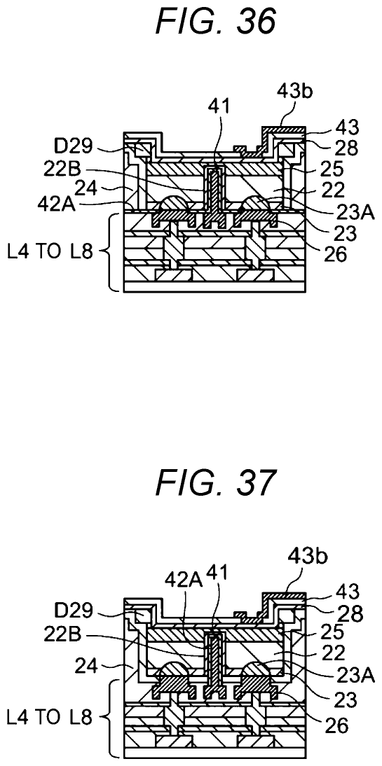

FIG. 36 is a cross-sectional view illustrating a partial structure example of a photodetection element in which an electrode layer 43b is further formed on the photodetection element which has been manufactured using the manufacturing steps illustrated in FIG. 35. As illustrated in FIG. 36, the electrode layer 43b is electrically connected to the transparent electrode 28 via a predetermined region formed in the first insulating film 43. In this manner, it is also possible to form a structure in which the photodetection element 1c illustrated in FIG. 26 is deformed.

FIG. 37 is a cross-sectional view illustrating a partial structure example of still another photodetection element. As illustrated in FIG. 37, the sidewall protective film 42A on the cap layer 23 is manufactured without being formed. In this manner, it is also possible to form a structure in which the photodetection element 1c illustrated in FIG. 26 is deformed.

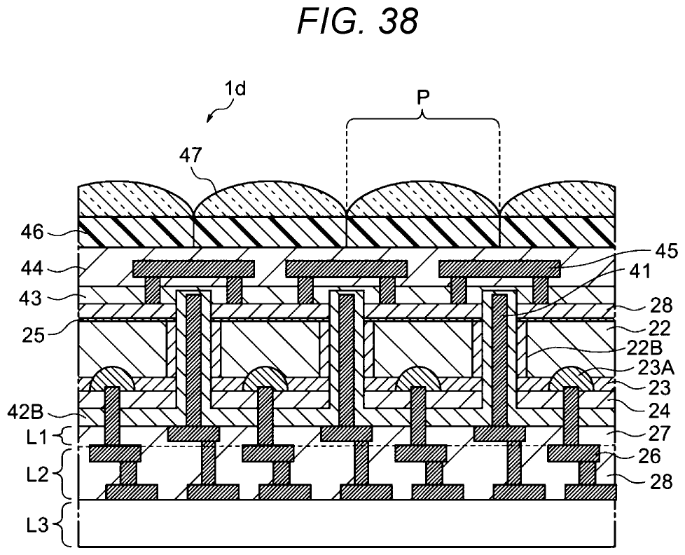

FIG. 38 is a cross-sectional view illustrating an example in which the sidewall protective film 42 of the photodetection element 1a illustrated in FIG. 4 is formed with a sidewall protective film 42B doped with phosphorus (P). That is, the sidewall protective film 42B of the photodetection element 1d has a film thickness of, for example, 2 to 20 nm, and is doped with phosphorus (P). The doping concentration of phosphorus is, for example, 1e20^{˜}22 cm⁻³. The sidewall protective film 42B includes, for example, any one of phosphorated quartz nitrite (PSG: Phosphosilicate Glass), phosphorus nitride (PxNy), and phosphorus oxide (PxOy). As a result, in addition to the effects described in the first embodiment, an intended interface state can be formed for any of indium gallium arsenide (InGaAs) and indium phosphide (InP) in the photoelectric conversion layer 22, the cap layer 23, and the compound semiconductor layer 25, and the dark current can be more efficiently suppressed.

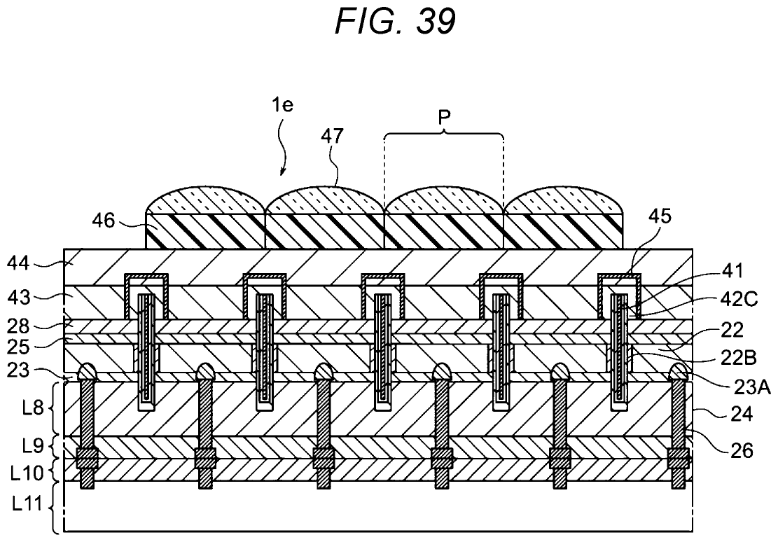

FIG. 39 is a cross-sectional view illustrating an example in which a sidewall protective film 42 of a photodetection element 1g to be described later in a third embodiment is formed with an insulating film doped with phosphorus (P). That is, a sidewall protective film 42C of the photodetection element 1e has a film thickness of, for example, 2 to 20 nm, and is doped with phosphorus (P). The doping concentration of phosphorus is, for example, 1e20^{˜}22 cm⁻³. The sidewall protective film 42C includes, for example, any one of phosphorated quartz nitrite (PSG: Phosphosilicate Glass), phosphorus nitride (PxNy), and phosphorus oxide (PxOy). As a result, in addition to the effect of the photodetection element 1g described later in the third embodiment, an intended interface state can be formed for any of indium gallium arsenide (InGaAs) and indium phosphide (InP) in the photoelectric conversion layer 22, the cap layer 23, and the compound semiconductor layer 25, and the dark current can be more efficiently suppressed. Note that details of the photodetection elements 1e and 1g will be described later in the third embodiment.

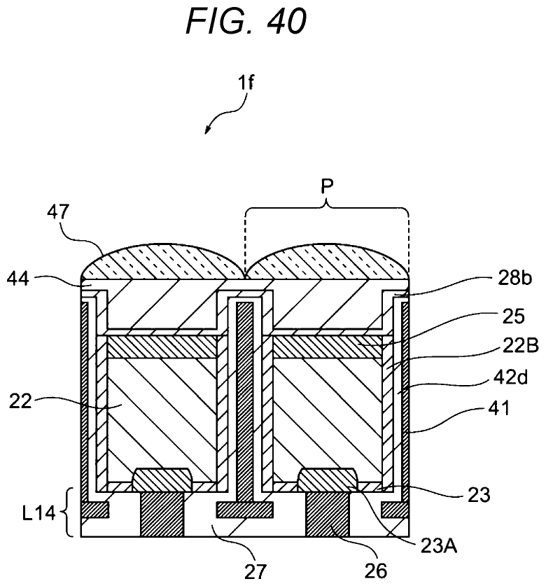

FIG. 40 is a cross-sectional view illustrating an example in which a sidewall protective film 42 of a photodetection element 1i described later in a fourth embodiment is formed with an insulating film doped with phosphorus (P). That is, a sidewall protective film 42d of the photodetection element 1i has a film thickness of, for example, 2 to 20 nm, and is doped with phosphorus (P). The doping concentration of phosphorus is, for example, 1e20^{˜}22 cm⁻³. The sidewall protective film 42d contains, for example, any of phosphorated quartz nitrite (PSG: Phosphosilicate Glass), phosphorus nitride (PxNy), and phosphorus oxide (PxOy). As a result, in addition to the effect of the photodetection element 1g described later in the third embodiment, an intended interface state can be formed for any of indium gallium arsenide (InGaAs) and indium phosphide (InP) in the photoelectric conversion layer 22, the cap layer 23, and the compound semiconductor layer 25, and the dark current can be more efficiently suppressed. Note that details of the photodetection element 1i will be described later in the fourth embodiment.

As described above, the sidewall protective film 42A according to the present embodiment includes an insulating film doped with phosphorus (P). As a result, an intended interface state can be formed for both indium gallium arsenide (InGaAs) and indium phosphide (InP). An intended interface state can be formed for any of indium gallium arsenide (InGaAs) and indium phosphide (InP) in the photoelectric conversion layer 22, the cap layer 23, and the compound semiconductor layer 25, and the dark current can be more efficiently suppressed.

### Third Embodiment

An electronic device according to a third embodiment is different from the electronic device according to the first embodiment in that a through hole (groove) in which a second light shielding body 41 of a photodetection element is embedded is formed from a light receiving side. Hereinafter, differences from the electronic device according to the first embodiment will be described.

### [Configuration Example of Photodetection Element]

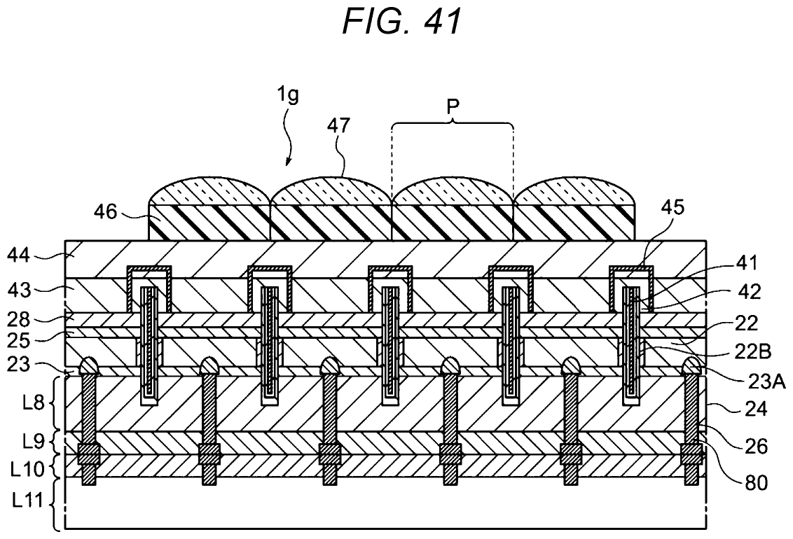

FIG. 41 is a partial cross-sectional view of the photodetection element according to the present embodiment. The photodetection element 1g is applied to, for example, an infrared sensor or the like, and includes a plurality of pixels P (see FIG. 2) arranged two-dimensionally. Functional components equivalent to those of the photodetection element 1a according to the first embodiment are denoted by the same reference numerals, and the description thereof may be omitted. In addition, even in the configuration denoted with the same number, the shape, material, dimension, manufacturing order, and the like may be changed from those of the photodetection element 1a according to the first embodiment.

The photodetection element 1g has a photoelectric conversion layer 22, and a cap layer 23 and a protective film 24 are sequentially formed on one surface of the photoelectric conversion layer 22. On the other surface of the photoelectric conversion layer 22, a compound semiconductor layer 25, a transparent electrode 28, a first insulating film 43, a second insulating film 44, a color filter 46, and an on-chip lens 47 are provided in this order.

In addition, layer wiring boards L8, L9, L10, and L11 are sequentially formed on one surface of the protective film 24. In the photoelectric conversion layer 22 and the cap layer 23, a first conductivity type region 23A is provided for each pixel P. The photodetection element 1g has a first electrode 26 penetrating the protective film 24, and the first conductivity type region 23A and a ROIC (Readout Integrated Circuit) of the multilayer wiring board L11 are electrically connected by the first electrode 26. In each of the layer wiring boards L9 and L10, a wiring portion is formed in an insulating film.

A through hole that penetrates the transparent electrode 28, the compound semiconductor layer 25, the photoelectric conversion layer 22, and the cap layer 23 from the middle of the first insulating film 43 and stops at the protective film 24 is provided between the adjacent pixels P. The sidewall protective film 42 and the second light shielding body 41 as a light shielding structure are embedded in the through hole.

The second light shielding body 41 is provided between the adjacent pixels P, and is provided in, for example, a lattice shape in plan view as described later. Light enters the photoelectric conversion layer 22 from between the adjacent second light shielding bodies 41. In this manner, by forming the light shielding structure penetrating the photoelectric conversion layer 22, the cap layer 23, the compound semiconductor layer 25, and the transparent electrode 28 between the pixels P, color mixing between the pixels P is suppressed.

Since the first insulating film 43 according to the present embodiment forms the through hole from the light receiving side, it can be configured without being limited by the processing selection ratio. The first insulating film 43 is, for example, silicon oxide (SiO₂), silicon nitride (SiN), aluminum oxide (Al₂O3), hafnium oxide (HfO₂), or the like. Further, the total film thickness is, for example, 50 to 300 nm.

On the other hand, the protective film 24 in which the through hole stops is opposite to the light receiving side, and the influence on the light reception amount is limited. Therefore, the uniformization of the length of the through hole in the protective film 24 can be reduced more than that on the light receiving side. On the other hand, since it is required to suppress variation in the protruding amount of the through hole on the light receiving side, the protruding amount of the through hole is uniformized by chemical mechanical polishing (CMP) processing of the first insulating film 43 as described later.

The sidewall protective film 42 and the second insulating film 44 include, for example, an inorganic insulating material. Examples of the inorganic insulating material include silicon nitride (SiN), aluminum oxide (Al₂O3), silicon oxide (SiO₂), and hafnium oxide (HfO₂). In addition, as described in the second embodiment, it is also possible to form an insulating film containing phosphorus (see FIG. 39) on the sidewall protective film 42.

The compound semiconductor layer 25 includes, for example, a p-type or n-type compound semiconductor. For example, n-type indium phosphide (InP) can be used for the compound semiconductor layer 25.

Examples of the transparent conductive material of the transparent electrode 28 include indium-tin oxide (including ITO, Sn-doped In₂O3, crystalline ITO and amorphous ITO), IFO (F-doped In₂O₃), tin oxide (SnO₂), ATO (Sb-doped SnO₂), FTO (F-doped SnO₂), zinc oxide (including Al doped ZnO, B doped Zno, and Ga doped ZnO), indium oxide-zinc oxide (IZO), titanium oxide (TiO₂), spinel-type oxide, and oxide having a YbFe₂O₄ structure.

A third electrode 45 connecting the pixels P is configured to penetrate the first insulating film 43 and the second insulating film 44. The third electrode 45 electrically connects the transparent electrodes 28 between the pixels P.

The photoelectric conversion layer 22 absorbs light having a predetermined wavelength (for example, light having a wavelength in the infrared region) to generate signal charges (electrons or holes), and includes, for example, a group III-V semiconductor. The photoelectric conversion layer 22 is, for example, a layer common to the respective pixels P, and is continuously provided between the pixels P on one surface of the compound semiconductor layer 25.

Examples of the group III-V semiconductor for the photoelectric conversion layer 22 include indium gallium arsenide (InGaAs). The composition of InGaAs is, for example, InxGa (1-x) As (x:0<x≤1). In order to increase the sensitivity in the infrared region, x≥0.4 is preferable. An example of the composition of the photoelectric conversion layer 22 lattice-matched with the compound semiconductor layer 25 including InP is In0.53Ga0.47As.

The photoelectric conversion layer 22 according to the present embodiment includes, for example, an n-type (second conductivity type) group III-V semiconductor, and contains a group IV element or a group VI element to be an n-type impurity. The group IV element is, for example, C (carbon), Si (silicon), Ge (germanium), and Sn (tin), and the group VI element is, for example, S (sulfur), Se (selenium), and Te (tellurium). The concentration of the n-type impurity is, for example, 2×10¹⁷/cm³ or less. The photoelectric conversion layer 22 may include a p-type (first conductivity-type) group III-V semiconductor.

In the present embodiment, the second conductivity type region 22B penetrating the photoelectric conversion layer 22 in the thickness direction is provided between the adjacent first conductivity type regions 23A. As a result, for example, movement of charges between the pixels P can be prevented.

The second conductivity type region 22B is, for example, an n-type impurity region having a higher concentration than the regions of the other photoelectric conversion layers 22. The impurity concentration of the second conductivity type region 22B is preferably 3 times or more the impurity concentration of the regions of the other photoelectric conversion layers 22. The second conductivity type region 22B includes, for example, a group IV element or a group VI element to be an n-type impurity. The group IV element is, for example, C (carbon), Si (silicon), Ge (germanium), and Sn (tin), and the group VI element is, for example, S (sulfur), Se (selenium), and Te (tellurium). The concentration of the n-type impurity in the second conductivity type region 22B is, for example, 5×10¹⁶/cm³ or more. The width (length in the X direction in FIG. 1) of the second conductivity type region 22B is, for example, 50 nm to 500 nm. The second conductivity type region 22B is provided between the adjacent pixels P, and is provided in, for example, a lattice shape in plan view as described later.

The cap layer 23 is provided between the photoelectric conversion layer 22 and the protective film 24. The cap layer 23 has the first conductivity type region 23A provided for each pixel P, whereby the pixels are electrically separated from each other.

The first conductivity type regions 23A are provided apart from each other for each pixel P. The first conductivity type region 23A is a region to which the signal charge generated in the photoelectric conversion layer 22 moves, and is, for example, a region containing a p-type impurity (p-type impurity region). The first conductivity type region 23A contains p-type impurities such as Zn (zinc), for example.

The protective film 24 includes, for example, an inorganic insulating material. Examples of the inorganic insulating material include silicon nitride (SiN), aluminum oxide (Al₂O3), silicon oxide (SiO₂), and hafnium oxide (HfO₂). The protective film 24 is provided with a through hole for each pixel P, and is provided with the first electrode 26 and the second light shielding body 41.

The first electrode 26 penetrates the protective film 24, and for example, a part thereof is embedded in the multilayer wiring boards L8 and L9. The first electrode 26 and the wirings of the multilayer wiring boards L9 and L10 are Cu—Cu connected. The first electrode 26 is provided for each pixel P, and is electrically connected to the corresponding first conductivity type region 23A and the ROIC of the corresponding multilayer wiring board L3. A voltage for reading signal charges generated in the photoelectric conversion layer 22 is supplied to the first electrode 26. One first electrode 26 may be provided for one pixel P, or a plurality of first electrodes 26 may be provided for one pixel P. Some of the plurality of first electrodes 26 provided for one pixel P may be dummy electrodes (electrodes that do not contribute to charge extraction).

The first electrode 26, the second light shielding body 41, and the third electrode 45 include, for example, any single substance of titanium (Ti), tungsten (W), titanium nitride (TiN), platinum (Pt), gold (Au), germanium (Ge), palladium (Pd), zinc (Zn), nickel (Ni), and aluminum (Al), or an alloy containing at least one of them. The first electrode 26 may be a single film of such a constituent material, or may be a laminated film obtained by combining two or more kinds.

### [Configuration Example of Layer Direction of Photodetection Element]

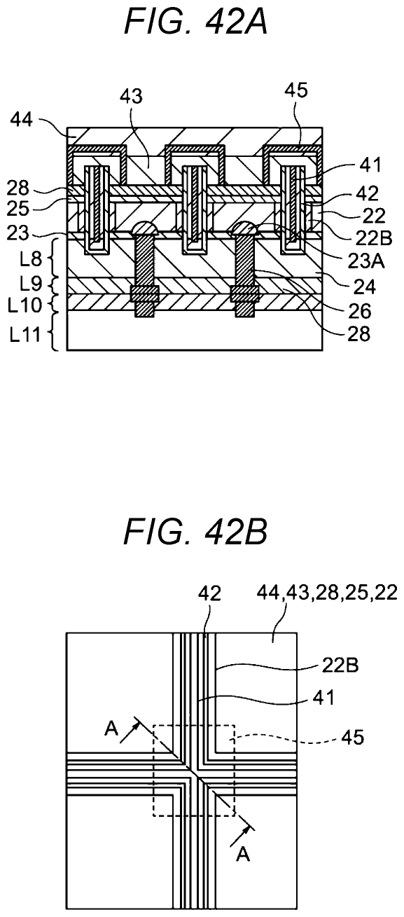

A configuration example in a layer direction of the photodetection element 1g will be described with reference to FIGS. 42A to 45B. FIG. 42A is an AA cross-sectional view of FIG. 42B. FIG. 42B is a plan view of four adjacent pixels p. FIG. 42B schematically illustrates a plan view of the photoelectric conversion layer 22, the transparent electrode 28, the compound semiconductor layer 25, the first insulating film 43, and the second insulating film 44. As illustrated in FIG. 42B, the second conductivity type region 22B and the sidewall protective film 42 are provided between the adjacent pixels P, and are provided in, for example, a lattice shape in plan view. Furthermore, the second light shielding body 41 is configured to surround the peripheries of the pixels P between the adjacent pixels P. That is, the second light shielding body 41 is provided in a lattice shape in plan view.

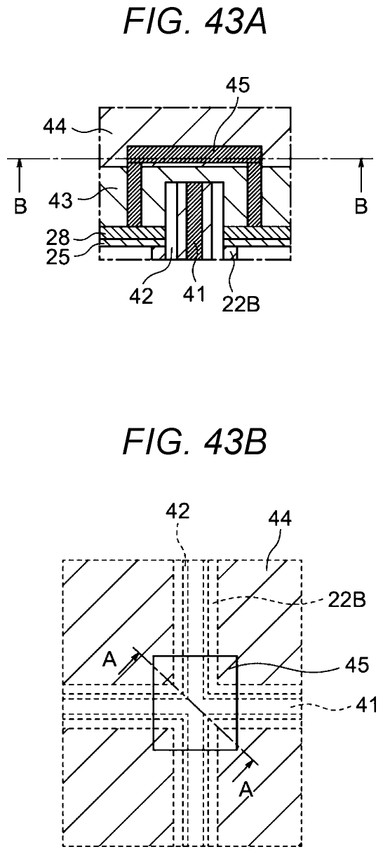

FIG. 43A is an AA cross-sectional view of FIG. 43B. A cross section of a partial region of the transparent electrode 28, the first insulating film 43, and the second insulating film 44 is illustrated. FIG. 43B is a BB cross-sectional view of FIG. 43A. As can be seen from these drawings, the second light shielding body 41 and the sidewall protective film 42 are not formed on the second insulating film 44, and are configured to stop before the first insulating film 43 is removed. On the other hand, the second conductivity type region 22B is formed in the photoelectric conversion layer 22. The square head region of the third electrode 45 is configured such that the range covering the pixel P is smaller.

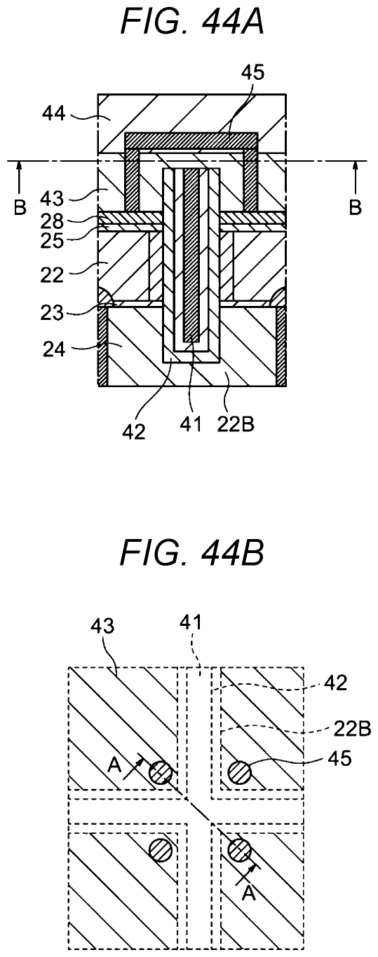

FIG. 44A is an AA cross-sectional view of FIG. 44B. A cross section of a partial region of the photoelectric conversion layer 22, the protective film 24, the transparent electrode 28, the first insulating film 43, and the second insulating film 44 is illustrated. FIG. 44B is a BB cross-sectional view of FIG. 44A. As can be seen from these drawings, the wiring portion of the third electrode 45 is formed in a columnar shape. A wiring portion of the third electrode 45 is formed at an adjacent corner portion of the pixel P, but the present invention is not limited thereto. For example, the wiring of the third electrode 45 may be electrically connected to at least one location for each pixel P.

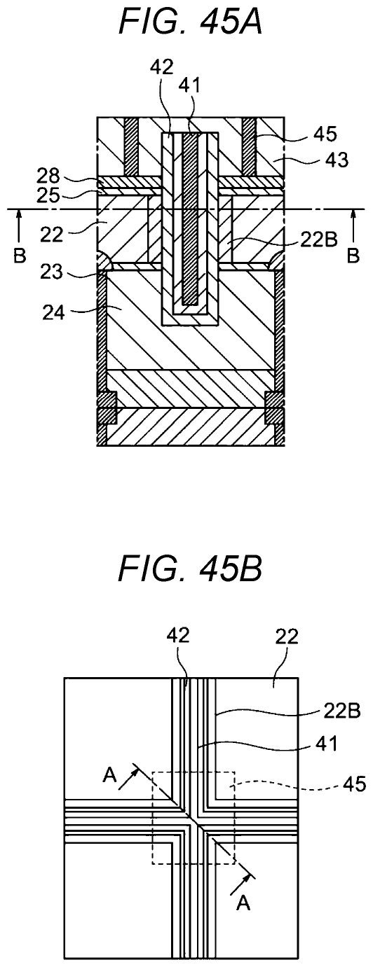

FIG. 45A is an AA cross-sectional view of FIG. 45B. A cross section of the photoelectric conversion layer 22, the cap layer 23, the protective film 24, the compound semiconductor layer 25, the transparent electrode 28, the first insulating film 43, the second insulating film 44, and a partial region of a layer wiring portion is illustrated. FIG. 45B is a BB cross-sectional view of FIG. 45A. As can be seen from these drawings, the second conductivity type region 22B, the second light shielding body 41, and the sidewall protective film 42 are provided between the adjacent pixels P.

### [Manufacturing Steps of Photodetection Element]

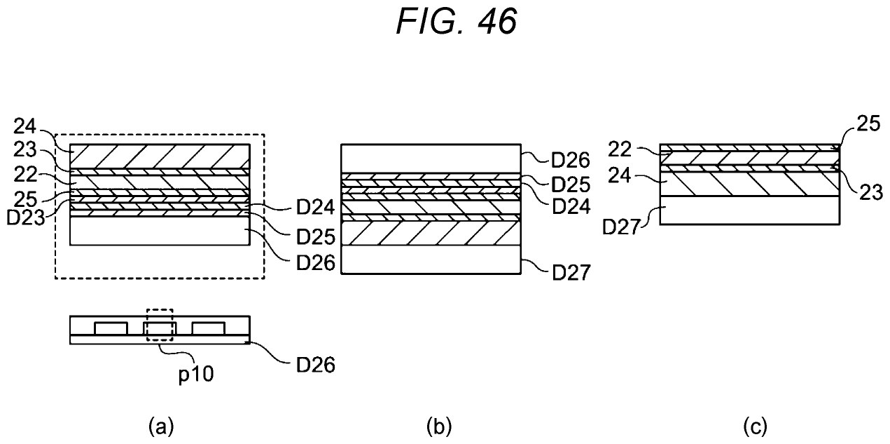

Although the configuration of the present embodiment has been described above, an example of a method for manufacturing the photodetection element 1g will be described below with reference to FIGS. 46 to 51. FIGS. 46 to 51 illustrate manufacturing steps of the photodetection element 1g (see FIG. 41) according to the present embodiment in order of steps.

FIG. 46 is a schematic cross-sectional view for explaining manufacturing steps of the photodetection element 1g (see FIG. 41) according to the third embodiment. As illustrated in FIG. 46(a), in the photodetection element 1g, the photoelectric conversion layer 22 is sequentially formed by, for example, epitaxial growth with respect to temporary film formations D25, D24, and D23, and is coupled to a temporary substrate D26. Then, the protective film 24 is formed and flattened by chemical mechanical polishing (CMP). As illustrated in the lower diagram of FIG. 46(a), the temporary substrate D26 includes a silicon wafer or the like. The upper diagram of FIG. 46(a) corresponds to the range p10. The temporary film formation D25 includes, for example, tetraethoxysilane (TEOS) or the like. The temporary film formation D24 includes, for example, tetraethoxysilane (TEOS) or the like. The temporarily film formation D23 is a cap layer and includes indium gallium arsenide (InGaAs) or the like, for example.

As illustrated in FIG. 46(b), the temporary substrate D26 is further bonded to the protective film 24. The temporary substrate D26 includes, for example, a silicon wafer. Subsequently, as illustrated in FIG. 46(c), the temporary film formation D24 to the temporary substrate D26 are removed by etching.

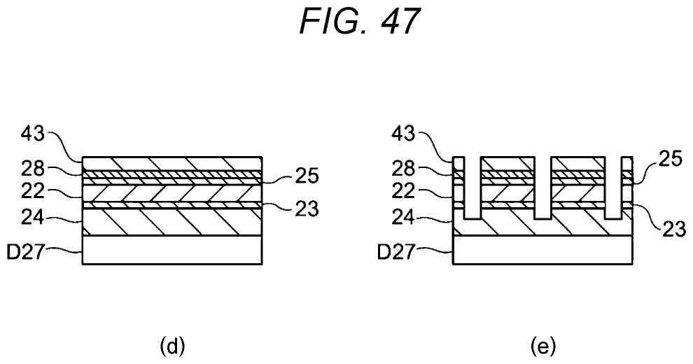

FIG. 47 is a schematic cross-sectional view illustrating steps subsequent to FIG. 46. As illustrated in FIG. 47(d), the transparent electrode 28 is formed on the protective film 24. For example, for the formation of the transparent electrode 28, it is possible to use physical vapor deposition methods (PVD methods) such as a vacuum vapor deposition method, a reactive vapor deposition method, various sputtering methods, an electron beam vapor deposition method, and an ion plating method, various chemical vapor deposition methods (CVD methods) including a pyrosol method, a method for thermally decomposing an organometallic compound, a spray method, a dip method, and an MOCVD method, an electroless plating method, and an electrolytic plating method. Then, the first insulating film 43 is formed.

Subsequently, as illustrated in FIG. 47(e), a through hole penetrating the first insulating film 43, the transparent electrode 28, the compound semiconductor layer 25, the photoelectric conversion layer 22, and the cap layer 23 and stopping at the protective film 24 is formed from the light receiving side by a photolithography technique and an etching technique.

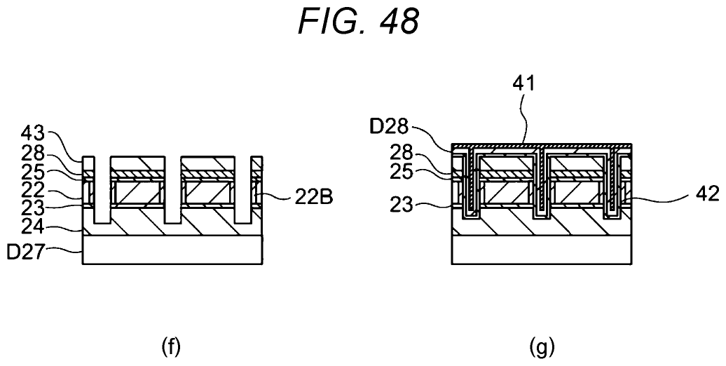

FIG. 48 is a schematic cross-sectional view illustrating steps subsequent to FIG. 47. As illustrated in FIG. 48(f), for example, a silicon oxide film (SiO₂) is formed in the through hole, and then heat treatment is performed for a long time. As a result, the n-type impurity spreads around the through hole, and the second conductivity type region 22B having a desired width is formed. The second conductivity type region 22B may be formed by gas layer diffusion or ion implantation in addition to the above-described solid-layer diffusion method. Since the film forming processing of the second conductivity type region 22B is performed before the layer wiring boards L8, L9, L10, and L11 are formed, thermal deterioration of the layer wiring boards L8, L9, L10, and L11 is suppressed.

Subsequently, as illustrated in FIG. 48(g), the sidewall protective film 42 is formed in the through hole by, for example, atomic layer deposition (ALD). Subsequently, the insulating film D28 is further formed. Then, a shielding layer including the second electrode 41 is formed in the through hole of the first insulating film 43. Note that, as illustrated in FIG. 39, a sidewall protective film 42C containing phosphorus (P) may be formed.

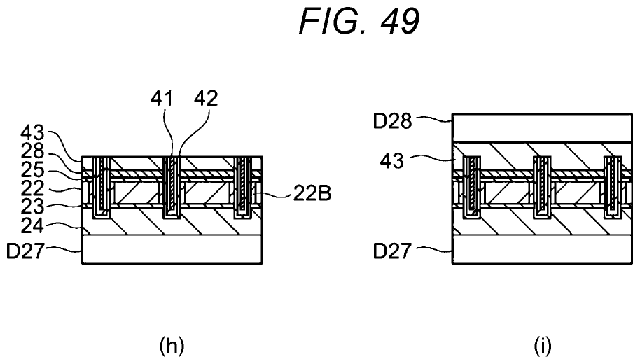

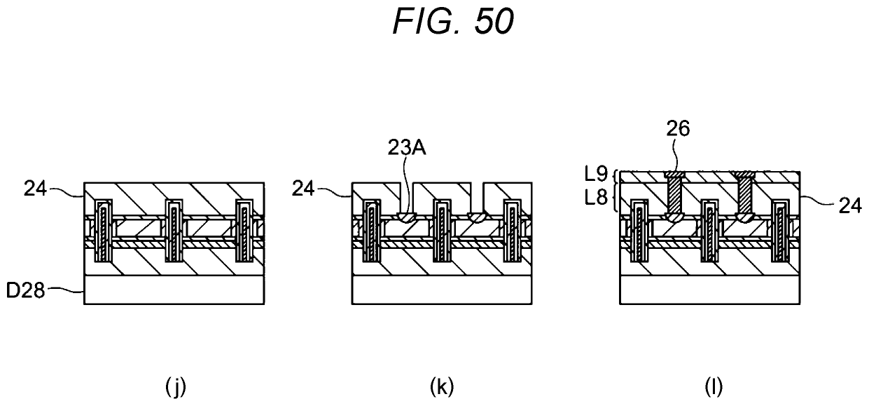

FIG. 49 is a schematic cross-sectional view illustrating steps subsequent to FIG. 48. As illustrated in FIG. 49(h), a part of the shielding layer, the insulating film D28, and the first insulating film 43 is removed by, for example, a chemical mechanical polishing (CMP) technique. As a result, the upper surface (light receiving side) of the first insulating film 43 including the second electrode 41 and the sidewall protective film 42 is flattened. In this manner, the length of the light receiving side of the second electrode 41 is made uniform. Subsequently, as illustrated in FIG. 49(i), the first insulating film 43 is further formed by epitaxial growth, for example. Then, the temporary substrate D28 is bonded to the first insulating film 43.

FIG. 50 is a schematic cross-sectional view illustrating steps subsequent to FIG. 49. As illustrated in FIG. 50(j), the temporary substrate D28 is removed by an etching technique. Subsequently, as illustrated in FIG. 50 (k), a through hole is formed in the protective film 24 by a photolithography technique and an etching technique. Then, p-type impurities (for example, zinc (Zn)) are vapor-phase diffused in the bottom region of the through hole. As a result, the photoelectric conversion layer 22 having the first conductivity type region 23A is formed. Subsequently, as illustrated in FIG. 50 (l), the first electrode 26 is formed in the through hole of the protective film 24.

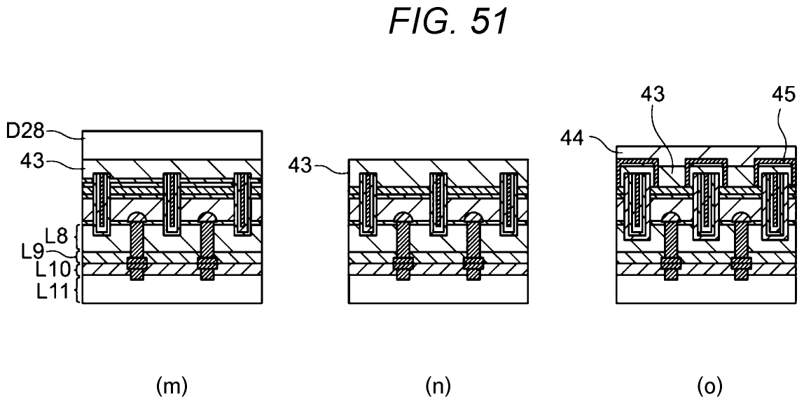

FIG. 51 is a schematic cross-sectional view illustrating steps subsequent to FIG. 50. As illustrated in FIG. 51(m), the layer wiring boards L8, L9, L10, and L11 are sequentially formed on one surface of the protective film 24. Subsequently, as illustrated in FIG. 51(n), the temporary substrate D28 is removed by, for example, an etching technique. Then, as illustrated in FIG. 51(O), the second insulating film 44 is formed by, for example, epitaxial growth, and the third electrode 45 is formed.

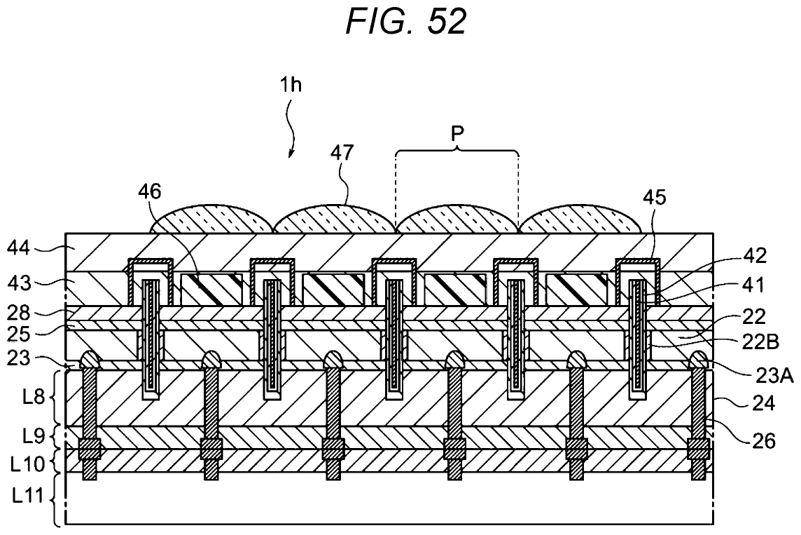

FIG. 52 is a cross-sectional view illustrating an example of a photodetection element 1h in which a color filter 46 is formed in the first insulating film 43. By configuring the color filter 46 in the first insulating film 43, the band limitation on the light reception of each pixel p can be performed with higher accuracy by shielding the second light shielding body 41.

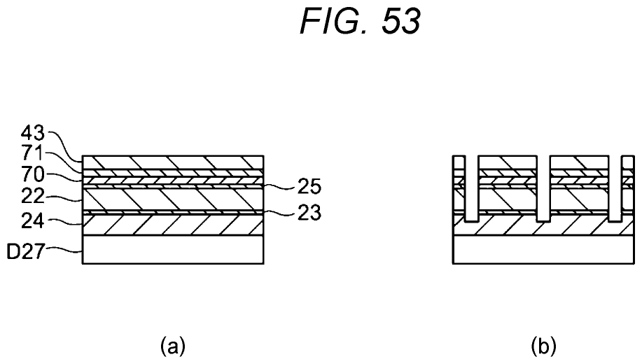

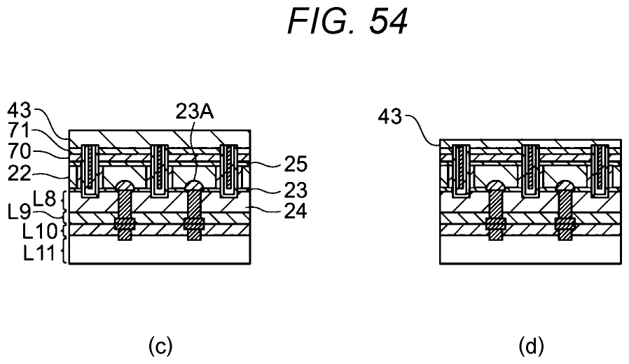

FIGS. 53 to 55 are methods of manufacturing a photodetection element different from those in FIGS. 46 to 51 in that the transparent electrode 28 is formed after the second electrode 41 and the sidewall protective film 42 are formed. Differences from FIGS. 46 to 51 will be described.

FIG. 53 is a schematic cross-sectional view for explaining other manufacturing steps of the photodetection element. As illustrated in FIG. 53(a), the state is different from the state of FIG. 47(d) in that oxide films 70 and 71 are formed between the photoelectric conversion layer 22 and the first insulating film 43 instead of the transparent electrode 28.

Subsequently, as illustrated in FIG. 53(b), a through hole penetrating the first insulating film 43, the oxide films 70 and 71, the compound semiconductor layer 25, the photoelectric conversion layer 22, and the cap layer 23 and stopping at the protective film 24 is formed from the light receiving side by a photolithography technique and an etching technique.

FIG. 54 is a schematic cross-sectional view illustrating steps subsequent to FIG. 53. As illustrated in FIG. 54(c), the first insulating film 43 is formed after the processing of FIG. 47(f) to 47(h) is performed. Subsequently, as illustrated in FIG. 54(d), the thickness of the first insulating film 43 is adjusted by an etching technique.

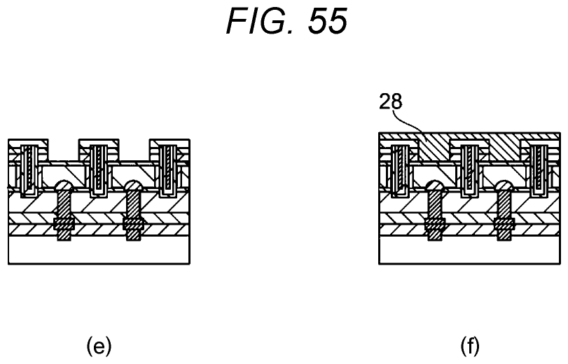

FIG. 55 is a schematic cross-sectional view illustrating steps subsequent to FIG. 54. As illustrated in FIG. 55(e), through holes are formed in the first insulating film 43 and the oxide films 70 and 71 by a photolithography technique and an etching technique. Then, the transparent electrode 28 including the through holes is formed. As described above, the through holes are protected by the first insulating film 43 and not exposed, and the characteristics can be improved without damage. In addition, since the transparent electrode 28 is electrically connected between the pixels P, an upper wiring is unnecessary.

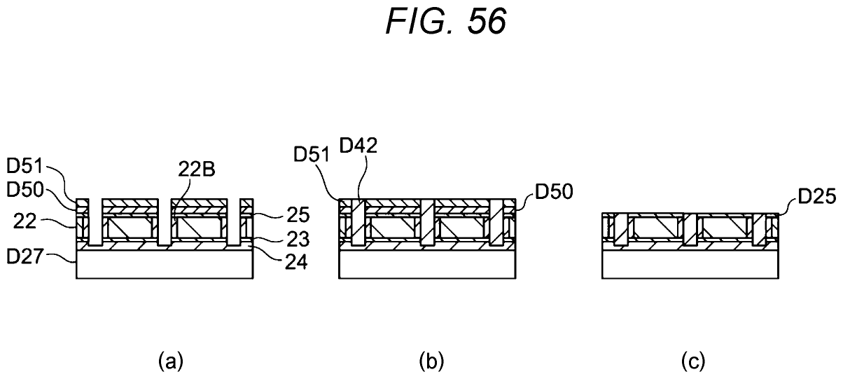

FIGS. 56 to 59 are methods of manufacturing a photodetection element different from those in FIGS. 53 to 55 in that a temporary insulating film is formed in a through hole. Differences from FIGS. 53 to 55 will be mainly described.

FIG. 56 is a schematic cross-sectional view for explaining other manufacturing steps of the photodetection element. As illustrated in FIG. 56(a), the state is different from the state of FIG. 47(d) in that oxide films D50 and D51 are formed on the photoelectric conversion layer 22 instead of the transparent electrode 28. Then, similarly FIG. 47(e) to (f), the second conductivity type region 22B is formed. Subsequently, as illustrated in FIG. 56(b), an insulating film D42 is formed in the through hole by epitaxial growth. Then, as illustrated in FIG. 56(c), the oxide films D50 and D51 are planarly removed by an etching technique, and the height of the opening on the incident light side of the through hole is made uniform.

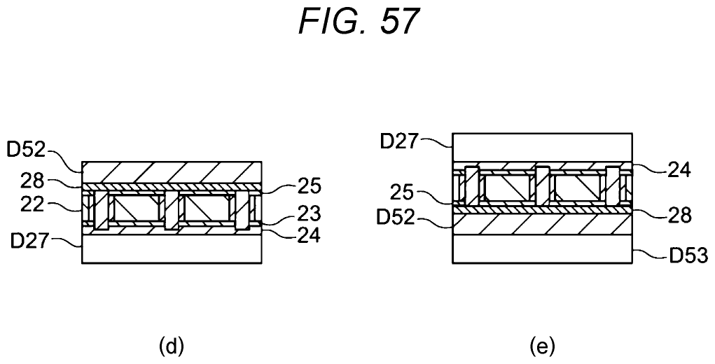

FIG. 57 is a schematic cross-sectional view illustrating steps subsequent to FIG. 56. As illustrated in FIG. 57(d), the transparent electrode 28 is formed, and the insulating film 52 is formed by epitaxial growth. Subsequently, as illustrated in FIG. 57(e), a temporary substrate D53 is bonded to an insulating film D52.

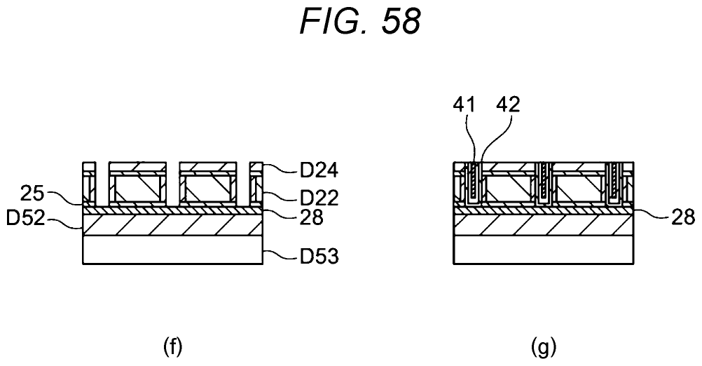

FIG. 58 is a schematic cross-sectional view illustrating steps subsequent to FIG. 57. As illustrated in FIG. 58(f), the temporary substrate D53 is removed, and the insulating film D42 in the through hole is removed by a photolithography technique and an etching technique. Subsequently, as illustrated in FIG. 57(g), the sidewall protective film 42 and the second light shielding body 41 are formed in the through hole. Note that the sidewall protective film 42 may be an insulating film doped with phosphorus (P).

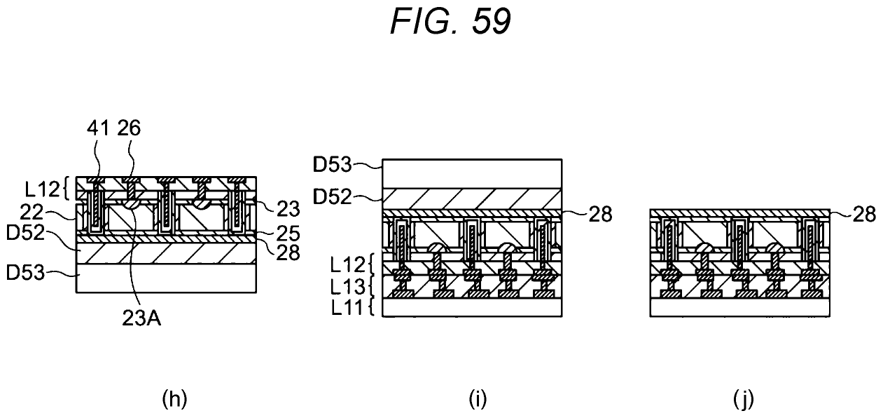

FIG. 59 is a schematic cross-sectional view illustrating steps subsequent to FIG. 58. As illustrated in FIG. 59(h), after an insulating film 80 is formed, a p-type impurity (for example, zinc (Zn)) is vapor-phase diffused in the bottom region of the through hole similarly FIG. 50(k) and 50(l). As a result, the photoelectric conversion layer 22 having the first conductivity type region 23A and the cap layer 23 are formed. Subsequently, the first electrode 26 and the second light shielding body 41 are formed. Subsequently, as illustrated in FIG. 59(i), the multilayer wiring boards L10 and L11 are formed and Cu—Cu bonded. Then, as illustrated in FIG. 59(k), the insulating film D52 and the temporary substrate D53 are removed by an etching technique. As described above, the through hole is protected by the transparent electrode and not exposed after the Cu—Cu bonding, and the characteristics can be improved without damage. In addition, since the transparent electrode 28 is electrically connected between the pixels P, an upper wiring is unnecessary.

As described above, the through hole penetrating the photoelectric conversion layer 22 is formed from the incident light side, and the through hole on the incident light side is made uniform by etching. As a result, the variation in the depth of the through hole on the surface opposite to the incident light side of the photoelectric conversion layer 22 is suppressed from affecting the amount of incident light between the pixels P. In addition, color mixing between the pixels P can be suppressed by the second electrode 41 formed in the through hole.

In addition, since the multilayer wiring boards L10 and L11 are formed and Cu—Cu bonded after the sidewall protective film 42 and the second light shielding body 41 are formed in the through hole, there is no heat application after the Cu—Cu bonding, and characteristic deterioration is suppressed. In addition, since the sidewall protective film 42 and the second light shielding body 41 are covered with the first insulating film or the transparent electrode 28 after being formed in the through-hole, deterioration of the sidewall protective film 42, the second light shielding body 41, and the photoelectric conversion layer 22 is suppressed in a post-manufacturing step.

### Fourth Embodiment

An electronic device according to a fourth embodiment is different from the electronic device according to the first embodiment in that a trench protrusion amount of a second electrode 41 penetrating a compound semiconductor layer 25 on a light receiving side is configured to improve light receiving separability between pixels. Hereinafter, differences from the electronic device according to the first embodiment will be described.

### [Configuration Example of Photodetection Element]

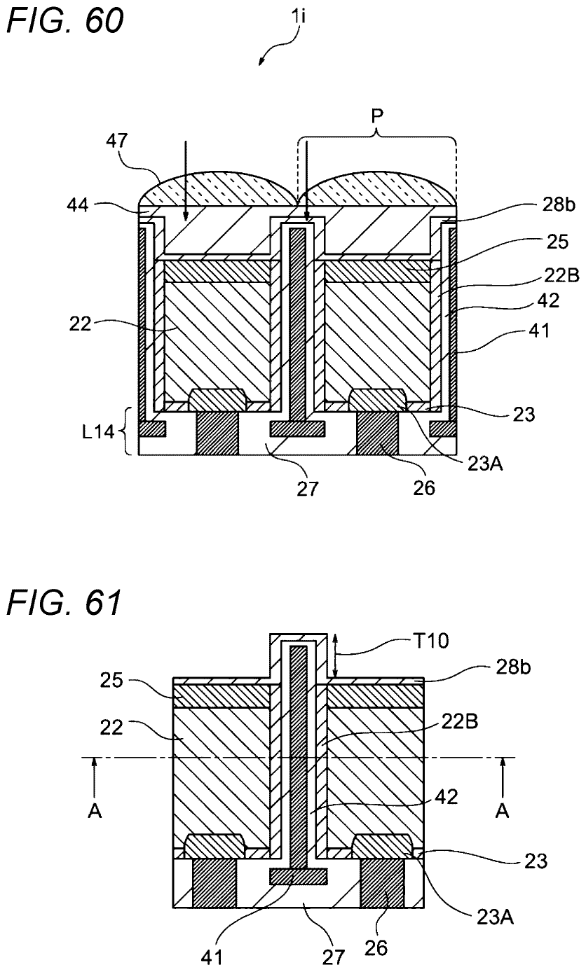

FIG. 60 is a partial cross-sectional view of a photodetection element according to the fourth embodiment. The photodetection element 1i is applied to, for example, an infrared sensor or the like, and includes a plurality of pixels P (see FIG. 2) arranged two-dimensionally. Configurations having functions equivalent to those of the photodetection element 1a according to the first embodiment are denoted by the same reference numerals, and description thereof may be omitted. In addition, even in the configuration denoted with the same number, the shape, material, dimension, manufacturing order, and the like may be changed from those of the photodetection element 1i according to the first embodiment.

A photodetection element 1i includes a photoelectric conversion layer 22, and a cap layer 23 is formed on one surface of the photoelectric conversion layer 22. On the other surface of the photoelectric conversion layer 22, a compound semiconductor layer 25, a transparent electrode 28b, a second insulating film 44, and an on-chip lens 47 are provided in this order. The compound semiconductor layer 25 is continuously formed for each pixel P, for example.

In addition, a layer wiring board L14 is formed on one surface of the cap layer 23, and a ROIC (Readout Integrated Circuit) is formed in a further lower layer.

In the photoelectric conversion layer 22 and the cap layer 23, a first conductivity type region 23A is provided for each pixel P. The photodetection element 1i includes a first electrode 26 penetrating the protective film 27, and the first conductivity type region 23A and a read out integrated circuit (ROIC) of the multilayer wiring board are electrically connected by the first electrode 26.

A through hole penetrating the photoelectric conversion layer 22, the cap layer 23, and the compound semiconductor layer 25 and stopping at the second insulating film 44 is provided between the adjacent pixels P. The sidewall protective film 42 and the second electrode 41 as a light shielding structure are embedded in the through hole. Further, the second electrode 41 penetrates the protective film 27 and is electrically connected to a read out integrated circuit (ROIC) of the multilayer wiring board.

The second electrode 41 is provided between the pixels P adjacent to each other, and is provided in, for example, a lattice shape in plan view as described later. Light enters the photoelectric conversion layer 22 from between the adjacent second electrodes 41. In this manner, by forming the light shielding structure penetrating the photoelectric conversion layer 22, the cap layer 23, and the compound semiconductor layer 25 between the pixels P, color mixing between the pixels P is suppressed. In addition, since the second electrode 41 penetrates the photoelectric conversion layer 22, the cap layer 23, and the compound semiconductor layer 25, the pinning effect due to the voltage application to the second electrode 41 is increased, and the dark current can be reduced.

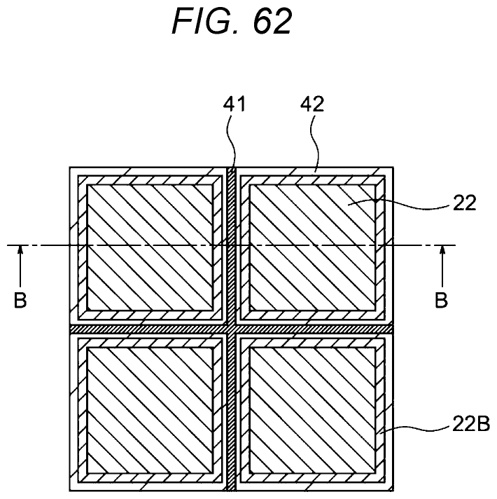

In addition, a trench protrusion amount T10 (see FIG. 61) can be configured to be 10 nm or more. Further, as described above, it is also possible to form an insulating film containing phosphorus on the sidewall protective film 42.

The second insulating film 44 includes, for example, an inorganic insulating material. Examples of the inorganic insulating material include silicon nitride (SiN), aluminum oxide (Al₂O₃), silicon oxide (SiO₂), and hafnium oxide (HfO₂).

A transparent electrode 28b including a transparent conductive material is formed on a surface of the compound semiconductor layer 25 on the light incident side. Examples of the transparent conductive material include indium-tin oxide (including ITO, Sn-doped In₂O₃, crystalline ITO and amorphous ITO), IFO (F-doped In₂O₃), tin oxide (SnO₂), ATO (Sb-doped SnO₂), FTO (F-doped SnO₂), zinc oxide (including Al doped ZnO, B doped Zno, and Ga doped ZnO), indium oxide-zinc oxide (IZO), titanium oxide (TiO₂), spinel-type oxide, and oxide having a YbFe₂O₄ structure. The transparent electrode 28b is formed on the compound semiconductor layer 25 and the sidewall protective film 42. As a result, even when the trench protrusion amount T10 (see FIG. 61) is increased, it is possible to suppress the range that hinders the incident light. Furthermore, as described later, since the second electrode 41 is formed from the side opposite to the incident side, it is possible to suppress the spread of the second electrode 41 at the intersection between the adjacent pixels P. As a result, it is possible to further suppress the range that hinders the incident light.

The compound semiconductor layer 25 includes, for example, a p-type or n-type compound semiconductor. For example, n-type indium phosphide (InP) can be used for the compound semiconductor layer 25. FIG. 60 illustrates a case where the photoelectric conversion layer 22 is provided in contact with one surface of the compound semiconductor layer 25, but another layer may be interposed between the compound semiconductor layer 25 and the photoelectric conversion layer 22.

Examples of the material of the layer interposed between the compound semiconductor layer 25 and the photoelectric conversion layer 22 include semiconductor materials such as InAlAs, Ge, Si, GaAs, and InP, and it is preferable to select a material having lattice matching between the compound semiconductor layer 25 and the photoelectric conversion layer 22. In the compound semiconductor layer 25, the above-described through hole is provided between the adjacent pixels P. Note that the compound semiconductor layer 25 is, for example, a layer common to the respective pixels P, and is continuously provided between the pixels P.

The photoelectric conversion layer 22 absorbs light having a predetermined wavelength (for example, light having a wavelength in the infrared region) to generate signal charges (electrons or holes), and includes, for example, a group III-V semiconductor. The photoelectric conversion layer 22 is, for example, a layer common to the respective pixels P, and is continuously provided between the pixels P on one surface of the compound semiconductor layer 25.

Examples of the group III-V semiconductor for the photoelectric conversion layer 22 include indium gallium arsenide (InGaAs). The composition of InGaAs is, for example, InxGa (1-x) As (x:0<x≤1). In order to increase the sensitivity in the infrared region, x≥0.4 is preferable. An example of the composition of the photoelectric conversion layer 22 lattice-matched with the compound semiconductor layer 25 including InP is In0.53Ga0.47As.

The photoelectric conversion layer 22 according to the present embodiment includes, for example, an n-type (second conductivity type) group III-V semiconductor, and contains a group IV element or a group VI element to be an n-type impurity. In a part of the photoelectric conversion layer 22 on the cap layer 23 side, the first conductivity type region 23A is provided continuously from the cap layer 23.

The second conductivity type region 22B is, for example, an n-type impurity region having a higher concentration than the regions of the other photoelectric conversion layers 22. The impurity concentration of the second conductivity type region 22B is preferably 3 times or more the impurity concentration of the regions of the other photoelectric conversion layers 22. In addition, the second conductivity type region 22B preferably has a thickness of 50 nm or more. The second conductivity type region 22B includes, for example, a group IV element or a group VI element to be an n-type impurity.

The cap layer 23 is provided between the photoelectric conversion layer 22 and the protective film 27. The cap layer 23 has the first conductivity type region 23A provided for each pixel P, whereby the pixels are electrically separated from each other. The cap layer 23 preferably includes a compound semiconductor having a band gap larger than that of the photoelectric conversion layer 22. For example, when the photoelectric conversion layer 22 including In0.53Ga0.47As (band gap 0.74 eV) is used, the cap layer 23 can include InP (band gap 1.34 eV) or InAlAs (band gap about 1.56 eV). A semiconductor layer may be interposed between the cap layer 23 and the photoelectric conversion layer 22. For this semiconductor layer, for example, InAlAs, Ge, Si, GaAs, InP, or the like can be used.

The plurality of first conductivity type regions 23A in the cap layer 23 is provided apart from each other for each pixel P. The first conductivity type region 23A is a region to which the signal charge generated in the photoelectric conversion layer 22 moves, and is, for example, a region containing a p-type impurity (p-type impurity region). The first conductivity type region 23A contains p-type impurities such as Zn (zinc), for example. The first conductivity type region 23A may not extend to a part of the photoelectric conversion layer 22, and may be provided up to an interface between the cap layer 23 and the photoelectric conversion layer 22, for example.

The protective film 27 is provided on the lower surface side of the cap layer 23 and includes, for example, an inorganic insulating material. Examples of the inorganic insulating material include silicon nitride (SiN), aluminum oxide (Al₂O3), silicon oxide (SiO₂), and hafnium oxide (HfO₂). A through hole is provided for each pixel P in the protective film 27, and the first electrode 26 and the second electrode 41 are provided in the through hole.

The first electrode 26 and the second electrode 41 penetrate the protective film 27 or penetrate the protective film 27 via the wiring portion. For example, a part thereof is embedded in the multilayer wiring board L14. The first electrode 26 and the second electrode 41 can be Cu—Cu connected to the wiring of the multilayer wiring board L2. The first electrode 26 is provided for each pixel P, and is electrically connected to the corresponding first conductivity type region 23A and the ROIC of the corresponding multilayer wiring board L3. A voltage for reading signal charges generated in the photoelectric conversion layer 22 is supplied to the first electrode 26.

FIG. 61 is a BB cross-sectional view of FIG. 62. FIG. 62 is an AA cross section of FIG. 61. As illustrated in FIG. 62, the second conductivity type region 22B and the sidewall protective film 42 are provided between the adjacent pixels P, and are provided in, for example, a lattice shape in plan view. In addition, the second electrode 41 is configured to surround the peripheries of the pixels P between the adjacent pixels P. That is, the second electrodes 41 are provided in a lattice shape in plan view.

When the second electrode 41 which is a light shielding structure is formed, so-called burr-like expansion occurs on a side where a material for forming the light shielding structure is input on the opening side. On the other hand, in the second electrode 41 according to the present embodiment, since the through hole (groove) is formed from the side opposite to the incident side, the opening is not formed on the incident light side, so that so-called burr-like expansion does not occur on the incident light side. That is, the end structure of the second electrode 41 on the incident light side can be configured to match the shape of the closed region at the end of the through hole. As a result, for example, it is possible to suppress the expansion of the intersection region of the second electrodes 41 which are light shielding structures formed in a lattice shape between the pixels P, and to suppress the reduction of the incident light.

### [Manufacturing Steps of Photodetection Element]

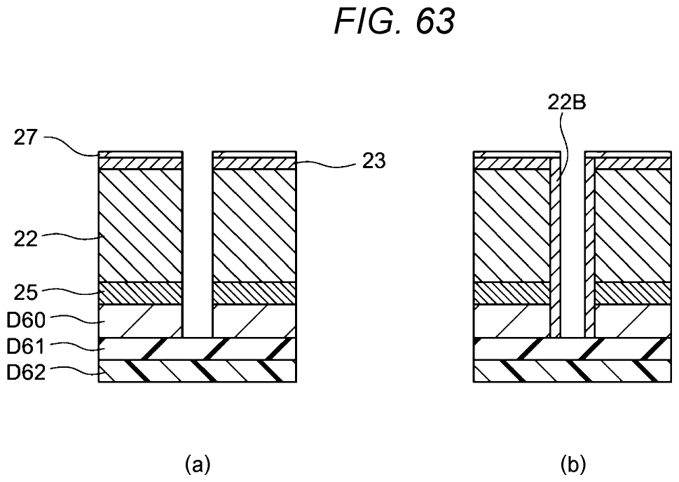

Although the configuration of the present embodiment has been described above, an example of a method for manufacturing the photodetection element 1i will be described below with reference to FIGS. 63 to 66. FIGS. 63 to 66 illustrate manufacturing steps of the photodetection element 1i (see FIG. 60) according to the present embodiment in order of steps.

FIG. 63 is a schematic cross-sectional view for explaining manufacturing steps of the photodetection element 1i (see FIG. 60) according to the present embodiment. As illustrated in FIG. 63(a), a bonding insulating film D61, a temporary semiconductor layer D60, the compound semiconductor layer 25, the photoelectric conversion layer 22, and the protective film 27 are formed on a support substrate D62. Then, a through hole penetrating the temporary semiconductor layer D60, the compound semiconductor layer 25, the photoelectric conversion layer 22, and the protective film 27 and stopping at the temporary semiconductor layer D60 is formed from the protective film 27 side opposite to the light receiving side by a photolithography technique and an etching technique. Subsequently, as illustrated in FIG. 63(b), the second conductivity type region 22B is formed around the through hole. Note that examples of a method for forming the second conductivity type region 22B include a gas phase diffusion method and a solid phase diffusion method of an impurity having the second conductivity type. When the second conductivity type is n-type, sulfur (S) and silicon (Si) can be exemplified as impurities.

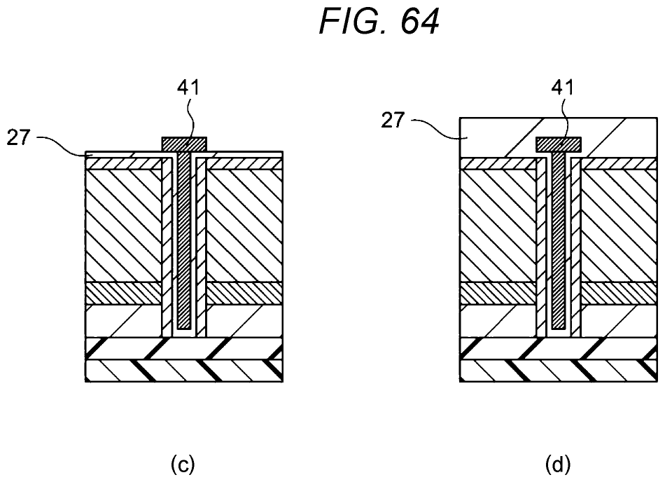

FIG. 64 is a schematic cross-sectional view illustrating steps subsequent to FIG. 63. As illustrated in FIG. 64(c), the second electrode 41 is formed after the sidewall protective film 42 is formed. Subsequently, as illustrated in FIG. 64(d), a protective film 27 is formed so as to cover the second electrode 41 and the sidewall protective film 42.

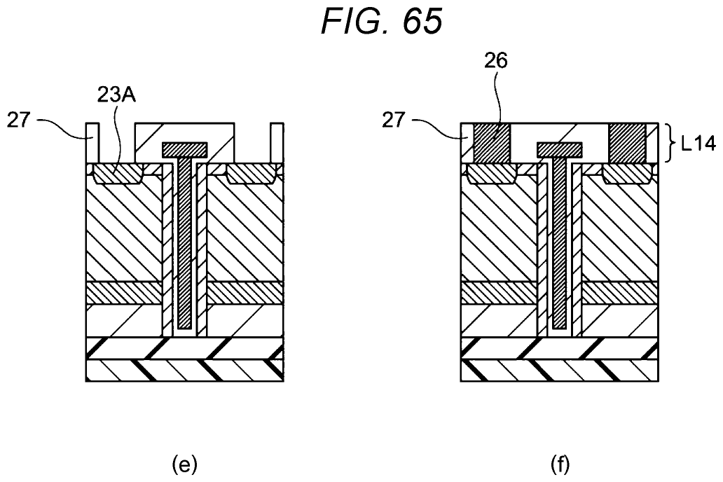

FIG. 65 is a schematic cross-sectional view illustrating steps subsequent to FIG. 64. As illustrated in FIG. 65(e), a through hole penetrating the protective film 27 and stopping at the surface of the cap layer 23 is formed. The through hole is formed by, for example, a photolithography technique and an etching technique. Then, p-type impurities (for example, zinc (Zn)) are vapor-phase diffused in the bottom region of the through hole. Thus, the cap layer 23 having the first conductivity type region 23A is formed. Subsequently, as illustrated in FIG. 65(f), the first electrode 26 is formed in the through hole. Then, the protective film 27 is further formed by epitaxial growth, and the layer wiring board L14 is formed.

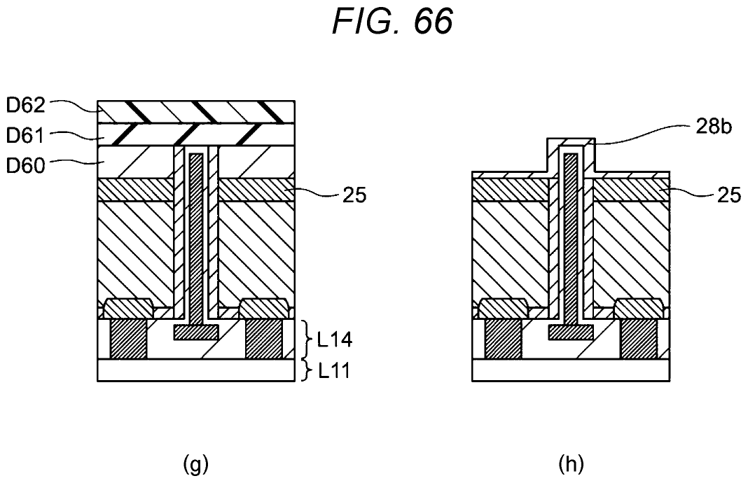

FIG. 66 is a schematic cross-sectional view illustrating steps subsequent to FIG. 65. As illustrated in FIG. 66(g), the layer wiring board L11 having ROIC is joined to the layer wiring board L14 by Cu—Cu bonding. Subsequently, as illustrated in FIG. 65(h), the support substrate D62, the bonding insulating film D61, and the temporary semiconductor layer D60 are removed by a photolithography technique and an etching technique. By taking a selection ratio between the bonding insulating film D61 and the protective film 27, it is possible to prevent Wet retraction of the protective film 27.

Subsequently, the transparent electrode 28b is formed. For the formation of the transparent electrode 28b, it is possible to use, for example, physical vapor deposition methods (PVD methods) such as a vacuum vapor deposition method, a reactive vapor deposition method, various sputtering methods, an electron beam vapor deposition method, and an ion plating method, various chemical vapor deposition methods (CVD methods) including a pyrosol method, a method for thermally decomposing an organometallic compound, a spray method, a dip method, and an MOCVD method, an electroless plating method, and an electrolytic plating method.

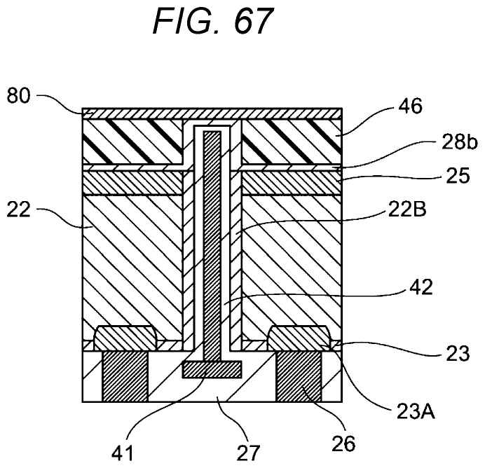

FIG. 67 is a cross-sectional view illustrating an example in which the color filter 46 and the insulating film 80 are formed. As illustrated in FIG. 67, by forming the color filter 46 between the protruding portions of the second electrodes 41, the wavelength separability between the pixels P is further improved.

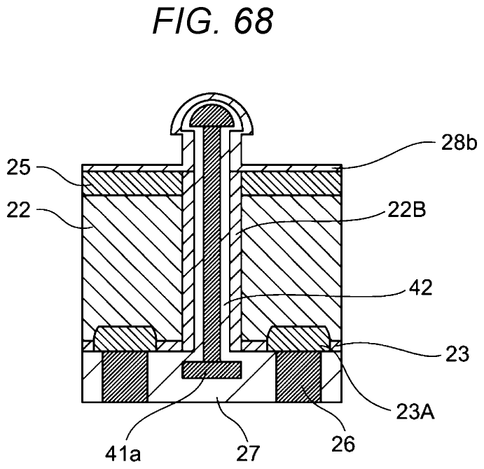

FIG. 68 is a cross-sectional view illustrating an example in which the shape of the end of the protruding portion of the second electrode 41 is changed. As illustrated in FIG. 68, by protruding the shape of the protruding portion of the second electrode 41, the separability of the incident light between the pixels P is further improved. That is, the shape of the protruding portion of the second electrode 41 has a region where the cross-sectional area increases from the incident side toward the opposite side. The similarity applies when the color filter 46 is formed between the protruding portions of the second electrodes 41.

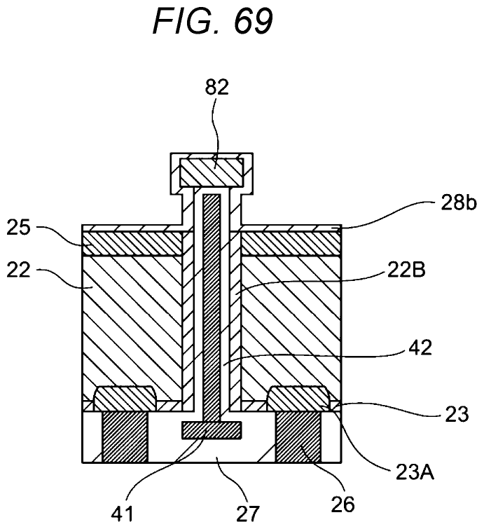

FIG. 69 is a cross-sectional view illustrating an example in which the transparent electrode 28b is formed while leaving a part of the bonding insulating film D61 at the protruding portion of the second electrode 41. By leaving a part of the bonding insulating film D61, deterioration of the characteristics of the second electrode 41 and the sidewall protective film 42 in the etching process is further suppressed.

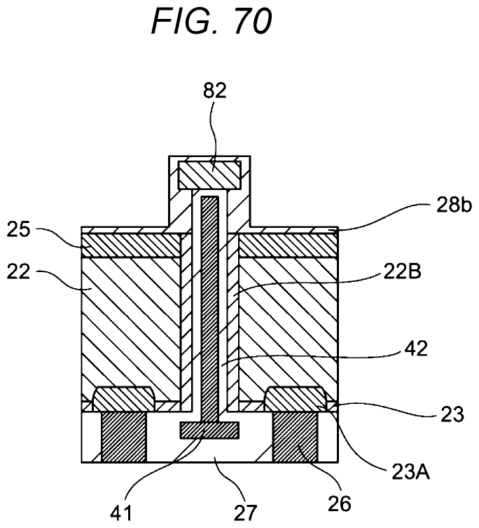

FIG. 70 is a cross-sectional view illustrating an example in which a transparent electrode 28c is formed while leaving a part of the bonding insulating film D61 at the protruding portion of the second electrode 41. By leaving a part of the bonding insulating film D61, deterioration of the characteristics of the second electrode 41 and the sidewall protective film 42 in the etching process is further suppressed. Further, by protecting the periphery of the protruding portion of the second electrode 41 with the transparent electrode 28c, deterioration of the characteristics of the second electrode 41 and the sidewall protective film 42 in the etching process is further suppressed. In addition, by thickening the transparent electrode 28c around the protruding portion of the second electrode 41, it is possible to prevent the electrical connection of the transparent electrode 28c from being cut off.

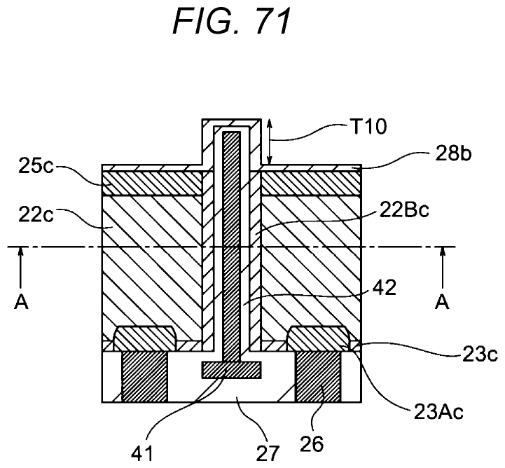

FIG. 71 is a cross-sectional view illustrating an example in which the conductivity type is different from that of the photodetection element illustrated in FIG. 60. The AA cross-sectional view is equivalent to FIG. 62.

A photoelectric conversion layer 22c includes a p-type (first conductivity type) group III-V semiconductor. A first conductivity type region 22Bc is, for example, a p-type impurity. For example, p-type impurities such as Zn (zinc) are contained. A second conductivity type region 23Ac contains, for example, a group IV element or a group VI element to be an n-type impurity. As described above, even when the conductivity type is changed, similar effects can be obtained.

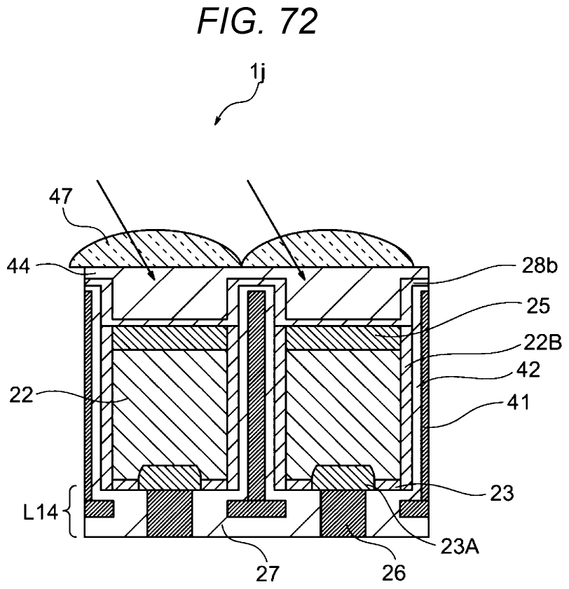

FIG. 72 is a cross-sectional view illustrating an example in which the position of the on-chip lens is aligned with the direction of the incident light. By matching the on-chip lens 47 with the direction of the incident light, a decrease in the amount of incident light is suppressed even in the peripheral portion of the photodetection element.

As described above, according to the present embodiment, effects similar to those of the first to third embodiments can be obtained. Furthermore, in the second electrode 41 according to the present embodiment, since the through hole (groove) is formed from the side opposite to the incident side, the end structure of the second electrode 41 on the incident light side can be configured to match the shape of the closed region at the end of the through hole. Furthermore, by forming the color filter 46 between the protruding portions of the second electrodes 41, which are the light shielding structures, from the compound semiconductor layer 25, the light receiving separability between the pixels P can be further improved. Also in this case, since the length and the shape of the protruding portion can be formed to match the shape of the closed region at the end of the through hole, a more suitable shape can be obtained.

### <Example of Application to In-Vivo Information Acquisition System>

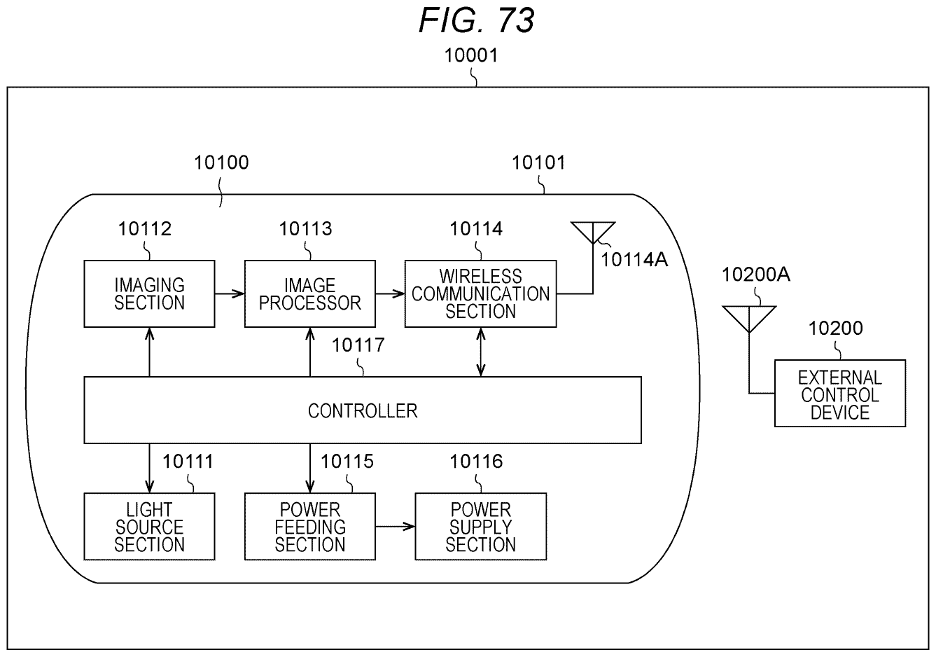

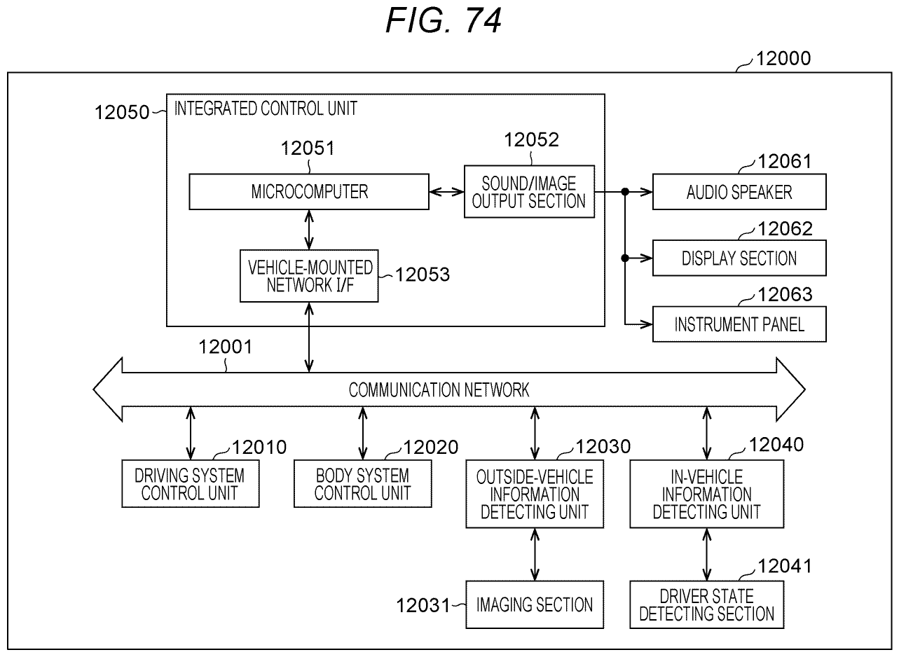

FIG. 73 is a block diagram illustrating an example of a schematic configuration of a patient in-vivo information acquisition system using a capsule endoscope to which the technology according to the present disclosure (present technology) can be applied.

An in-vivo information acquisition system 10001 includes a capsule endoscope 10100 and an external control device 10200.

The capsule endoscope 10100 is swallowed by a patient during examination. The capsule endoscope 10100 has an imaging function and a wireless communication function and sequentially takes images in organs (hereinafter, also referred to as in-vivo images) at a predetermined interval while moving in the organs such as the stomach and the intestine by peristaltic movement and the like until naturally discharged from the patient, and sequentially wirelessly transmits information regarding the in-vivo images to the external control device 10200 outside the body.

The external control device 10200 centrally controls the operation of the in-vivo information acquisition system 10001. Further, the external control device 10200 receives information about the internal images transmitted from the capsule endoscope 10100, and generates image data for displaying the internal images on a display device (not illustrated) on the basis of the received information about the internal images.

In the in-vivo information acquisition system 10001, it is possible to obtain as needed the in-vivo image obtained by imaging a state in the patient's body from when the capsule endoscope 10100 is swallowed until this is discharged in this manner.

Configurations and functions of the capsule endoscope 10100 and the external control device 10200 are described in further detail.

The capsule endoscope 10100 includes a capsule-shaped housing 10101, and includes a light source section 10111, an imaging section 10112, an image processor 10113, a wireless communication section 10114, a power feeding section 10115, a power supply section 10116, and a controller 10117 which are housed in the capsule-shaped housing 10101.

The light source section 10111 includes a light source such as a light emitting diode (LED) or the like, for example, and irradiates an imaging field of view of the imaging section 10112 with light.

The imaging section 10112 includes an optical system including an imaging element and a plurality of lenses provided on a preceding stage of the imaging element. Reflected light (hereinafter referred to as observation light) of light emitted toward a body tissue which is an observation target is condensed by the optical system and enters the imaging element. In the imaging section 10112, in the imaging element, the observation light incident thereon is photoelectrically converted, and an image signal corresponding to the observation light is generated. The image signal generated by the imaging section 10112 is provided to the image processor 10113.

The image processor 10113 includes a processor such as a central processing unit (CPU), a graphics processing unit (GPU), or the like, and performs various kinds of signal processing on the image signal generated by the imaging section 10112. The image processor 10113 provides the image signal subjected to signal processing to the wireless communication section 10114 as RAW data.

The wireless communication section 10114 performs predetermined processing such as modulation processing on the image signal that has been subjected to signal processing by the image processor 10113, and transmits the resultant image signal to the external control device 10200 via an antenna 10114A. Furthermore, the wireless communication section 10114 receives a control signal regarding drive control of the capsule endoscope 10100 from the external control device 10200 via the antenna 10114A. The wireless communication section 10114 provides the control signal received from the external control device 10200 to the controller 10117.

The power feeding section 10115 includes an antenna coil for power reception, a power regeneration circuit for regenerating power from current generated in the antenna coil, a booster circuit and the like. In the power feeding section 10115, the principle of what is called contactless charging is used to generate power.

The power supply section 10116 includes a secondary battery, and stores the power generated by the power feeding section 10115. In FIG. 73, in order to avoid complication of the drawing, illustration of an arrow or the like indicating a supply destination of power from the power supply section 10116 is omitted, but the power stored in the power supply section 10116 is supplied to the light source section 10111, the imaging section 10112, the image processor 10113, the wireless communication section 10114, and the controller 10117, and can be used for driving these sections.

The controller 10117 includes a processor such as a CPU, and appropriately controls driving of the light source section 10111, the imaging section 10112, the image processor 10113, the wireless communication section 10114, and the power feeding section 10115 according to the control signal transmitted from the external control device 10200.

The external control device 10200 includes a processor such as a CPU and a GPU, or a microcomputer, a control substrate or the like on which the processor and a storage element such as a memory are mounted in a mixed manner. The external control device 10200 controls the operation of the capsule endoscope 10100 by transmitting the control signal to the controller 10117 of the capsule endoscope 10100 via an antenna 10200A. In the capsule endoscope 10100, for example, an irradiation condition of the light to the observation target in the light source section 10111 may be changed by the control signal from the external control device 10200. Furthermore, an imaging condition (for example, a frame rate, an exposure value and the like in the imaging section 10112) may be changed by the control signal from the external control device 10200. Further, the contents of processing in the image processor 10113 and conditions for transmitting the image signal by the wireless communication section 10114 (for example, transmission interval, number of transmitted images, and the like) may be changed by the control signal from the external control device 10200.

Further, the external control device 10200 performs various image processing on the image signal transmitted from the capsule endoscope 10100, and generates image data for displaying the captured in-vivo image on the display apparatus. As the image processing, for example, various signal processing such as development processing (demosaic processing), image quality enhancement processing (band enhancement processing, super-resolution processing, noise reduction (NR) processing, and/or camera shake correction processing, and the like), and/or enlargement processing (electronic zoom processing) and the like can be performed. The external control device 10200 controls the drive of the display device, and causes the display device to display a captured internal image on the basis of the generated image data. Alternatively, the external control device 10200 may also cause a recording device (not illustrated) to record the generated image data, or cause a printing device (not illustrated) to make a printout of the generated image data.

An example of the in-vivo information acquisition system to which the technology according to the present disclosure can be applied has been described above. The technology according to the present disclosure can be applied to, for example, the imaging section 10112 among the above-described configurations. As a result, a clearer surgical site image can be obtained, so that the accuracy of the inspection is improved.

### <Application Example to Mobile Body>

The technology according to the present disclosure (the present technology) can be applied to various products. For example, the technology according to the present disclosure may be implemented as a device to be mounted on a mobile body of any kind, such as an automobile, an electric automobile, a hybrid electric automobile, a motorcycle, a bicycle, a personal mobility, an airplane, a drone, a ship, or a robot.

FIG. 74 is a block diagram illustrating a schematic configuration example of a vehicle control system as an example of a moving body control system to which the technology according to the present disclosure is applied.

The vehicle control system 12000 includes a plurality of electronic control units connected to each other via a communication network 12001. In the example illustrated in FIG. 73, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as functional components of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine or a driving motor, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various lamps such as a headlamp, a back-up lamp, a brake lamp, a turn indicator, or a fog lamp. In this case, a radio wave transmitted from a mobile device that substitutes for a key or signals of various switches may be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the captured image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light and outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether or not the driver is dozing.

The microcomputer 12051 can calculate a control target value for the driving force generating device, the steering mechanism, or the braking device on the basis of the information about the inside or outside of the vehicle, the information being obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS), the functions including vehicle collision avoidance or shock mitigation, following driving based on the following distance, vehicle speed maintaining driving, vehicle collision warning, vehicle lane departure warning, and the like.

Furthermore, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the surroundings of the vehicle, the information being obtained by the outside-vehicle information detecting unit 12030 or the in-vehicle information detecting unit 12040.

Furthermore, the microcomputer 12051 can output a control command to the body system control unit 12020, on the basis of the information about the outside of the vehicle obtained by the outside-vehicle information detecting unit 12030. For example, the microcomputer 12051 can perform cooperative control intended to prevent glare by controlling the headlamp to switch from high beam to low beam, for example, in accordance with the position of a preceding vehicle or an oncoming vehicle detected by the outside-vehicle information detecting unit 12030.

The sound/image output section 12052 transmits an output signal of at least one of a sound or an image to an output device capable of visually or auditorily notifying an occupant of the vehicle or the outside of the vehicle of information. In the example of FIG. 73, an audio speaker 12061, a display section 12062, and an instrument panel 12063 are illustrated as the output device. The display section 12062 may, for example, include at least one of an on-board display or a head-up display.

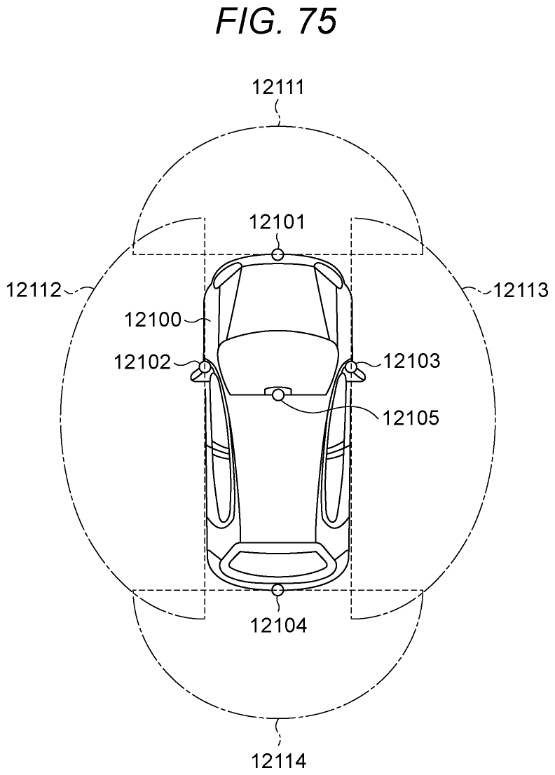

FIG. 75 is a diagram illustrating an example of the installation position of the imaging section 12031.

In FIG. 75, the imaging section 12031 includes imaging sections 12101, 12102, 12103, 12104, and 12105.

The imaging sections 12101, 12102, 12103, 12104, and 12105 are provided at positions, for example, the front nose, the sideview mirrors, the rear bumper, the back door, an upper portion of the windshield in the interior, and the like of the vehicle 12100. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly images of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 75 illustrates an example of imaging ranges of the imaging sections 12101 to 12104. An imaging range 12111 represents the imaging range of the imaging section 12101 provided to the front nose, imaging ranges 12112 and 12113 respectively represent the imaging ranges of the imaging sections 12102 and 12103 provided to the sideview mirrors, and an imaging range 12114 represents the imaging range of the imaging section 12104 provided on the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera including a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and travels in substantially the same direction as the vehicle 12100 at a predetermined speed (for example, equal to or more than 0 km/hour). Moreover, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving in which the vehicle travels autonomously without depending on the driver's operation, or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in captured images of the imaging sections 12101 to 12104. Such pedestrian recognition is, for example, performed by a procedure of extracting feature points in the images captured by the imaging sections 12101 to 12104 as infrared cameras and a procedure of determining whether or not it is a pedestrian by performing pattern matching processing on a series of feature points representing a contour of an object. When the microcomputer 12051 determines that there is a pedestrian in the captured images of the imaging sections 12101 to 12104 and recognizes the pedestrian, the sound/image output section 12052 controls the display section 12062 so that a rectangular contour for emphasis is displayed in a superimposed manner on the recognized pedestrian. Furthermore, the sound/image output section 12052 may also control the display section 12062 so that an icon or the like representing the pedestrian is displayed at a desired position.

In the above, an example has been described of the vehicle control system to which the technology according to the present disclosure can be applied. The technology according to the present disclosure can be applied to, for example, the imaging section 12031 or the like among the configurations described above. By applying the technology of the present disclosure to the imaging section 12031, a more easily viewable captured image can be obtained, by which fatigue of the driver can be reduced.

Although the present technology has been described with reference to the exemplary embodiments and the modifications, the present technology is not limited to the exemplary embodiments and the like, and various modifications can be made. For example, the layer configuration of the light receiving element described in the above embodiments and the like is an example, and another layer may be further included. In addition, the material and thickness of each layer are also examples, and are not limited to those described above.

Note that the effects described in the present specification are merely examples and are not limited thereto, and other effects may be provided.

Note that the present technology can have the following configurations.
(1)

A photodetection element including:
a photoelectric conversion layer that generates a signal charge in response to incidence of light; and
a light shielding structure having a wall shape and penetrating the photoelectric conversion layer, the light shielding structure having an opening on a side opposite to a light incident side and formed in a through hole having a groove shape and having a closed region on the light incident side.
(2)

The photodetection element according to (1), further including an insulating film formed on the light incident side of the photoelectric conversion layer, in which
an end of the light shielding structure having a wall shape on the light incident side is formed in the insulating film.
(3)

The photodetection element according to (2), further including a first semiconductor layer configured on the light incident side of the photoelectric conversion layer, in which
the light shielding structure having a wall shape further penetrates the first semiconductor layer.
(4)

The photodetection element according to (3), further including a second semiconductor layer configured on a side of the photoelectric conversion layer opposite to the light incident side, in which
the light shielding structure having a wall shape further penetrates the second semiconductor layer.
(5)

The photodetection element according to (4), further including:
a plurality of first conductivity type regions to which signal charges generated in the photoelectric conversion layer move; and
a second conductivity type region provided between the light shielding structures having a wall shape adjacent to each other while penetrating the photoelectric conversion layer.
(6)

The photodetection element according to (5), in which the photoelectric conversion layer is of a second conductivity type,
the second conductivity type region has a higher concentration than the photoelectric conversion layer, and
the second conductivity type region is formed in the second semiconductor layer.
(7)

The photodetection element according to (6), further including a transparent electrode configured on the light incident side of the photoelectric conversion layer, in which
the light shielding structure having a wall shape penetrates the transparent electrode.
(8)

The photodetection element according to (2), in which the insulating film includes any of silicon oxide (SiO2), silicon nitride (SiN), aluminum oxide (Al2O3), and hafnium oxide (HfO).
(9)

The photodetection element according to (3), in which a total film thickness of the insulating film is 50 to 300 nm.
(10)

The photodetection element according to (1), in which the photoelectric conversion layer is of a first conductivity type.
(11)

The photodetection element according to (1), in which a sidewall protective film is further provided between an inner wall in the through hole having a groove shape and the light shielding structure having a wall shape.
(12)

The photodetection element according to (11), in which the sidewall protective film is an insulating film doped with phosphorus (P), and the insulating film doped with phosphorus (P) contains at least one of phosphorated quartz nitrite (PSG: Phosphorous Glass), phosphorus nitride (PN), and phosphorus oxide (PO).
(13)

The photodetection element according to (11), in which the sidewall protective film is an insulating film doped with phosphorus (P), and has a film thickness of 2 to 20 nm, and a doping concentration of phosphorus is, for example, 1e20˜22 cm−3.
(14)

The photodetection element according to (7), in which the second conductivity type region and at least the second conductivity type region of the light shielding structure are electrically connected to a readout circuit unit.
(15)

The photodetection element according to (1), further including a color filter provided between the light shielding structures having a wall shape adjacent to each other while penetrating the photoelectric conversion layer.
(16)

The photodetection element according to (1), in which an end of the light shielding structure on the light incident side has a region in which a cross-sectional area increases from an incident side toward an opposite side.
(17)

A photodetection element including:
a photoelectric conversion layer that has at least one of indium gallium arsenide (InGaAs) or indium phosphide (InP) and generates a signal charge in response to incidence of light;
a light shielding structure having a wall shape and formed in a through hole having a groove shape and penetrating the photoelectric conversion layer; and
a sidewall protective film formed between an inner wall in the through hole having a groove shape and the light shielding structure having a wall shape, in which
the sidewall protective film is an insulating film doped with phosphorus (P).
(18)

A method for manufacturing a photodetection element, the method including:
forming a first temporary substrate, an initial insulating film, a first semiconductor layer, a photoelectric conversion layer, a second semiconductor layer, an insulating film, and a second temporary substrate in layers;
deleting the first temporary substrate and the initial insulating film;
forming a first insulating film on a surface side of the first semiconductor layer opposite to the photoelectric conversion layer;
forming a groove-shaped through hole penetrating the second semiconductor layer, the photoelectric conversion layer, and the first semiconductor layer from the second semiconductor layer side and stopping at the first insulating film; and
forming a wall-shaped protective film and a light shielding body from the second semiconductor layer side in the groove-shaped through hole.

(19)

A method for manufacturing a photodetection element, the method including:
forming at least a temporary substrate, a protective film, a photoelectric conversion layer, and an insulating film;
forming a through hole having a groove shape and penetrating the insulating film and the photoelectric conversion layer from the insulating film and stopping at the protective film;
forming a protective film having a wall shape and a light shielding body from the insulating film in the through hole having a groove shape; and
etching ends of the insulating film, the protective film, and the light shielding body so that the insulating film has a flat surface.
(20)

An electronic device including:
the photodetection element according to (1); and
an optical system that focuses light on the photodetection element.

Aspects of the present disclosure are not limited to the above-described individual embodiments, but include various modifications that can be conceived by those skilled in the art, and the effects of the present disclosure are not limited to the above-described contents. That is, various additions, modifications, and partial removals can be made without departing from the conceptual idea and spirit of the present disclosure derived from the contents defined in the claims and equivalents thereof.

### REFERENCE SIGNS LIST

1a to 1i Photodetection element
2 Electronic device
22 Photoelectric conversion layer
23 Cap layer
23A First conductivity type region
24, 27 Protective film
25 Compound semiconductor layer
28 Transparent electrode
41 Second electrode
42 Sidewall protective film
43 First insulating film
46 Color filter
232 Temporary substrate
238 Temporary substrate
240 Temporary substrate
D61 Bonding insulating film
D60 Temporary semiconductor layer

1. A photodetection element comprising:
a photoelectric conversion layer that generates a signal charge in response to incidence of light; and
a light shielding structure having a wall shape and penetrating the photoelectric conversion layer, the light shielding structure having an opening on a side opposite to a light incident side and formed in a through hole having a groove shape and having a closed region on the light incident side.

2. The photodetection element according to claim 1, further comprising an insulating film formed on the light incident side of the photoelectric conversion layer, wherein
an end of the light shielding structure having a wall shape on the light incident side is formed in the insulating film.

3. The photodetection element according to claim 2, further comprising a first semiconductor layer configured on the light incident side of the photoelectric conversion layer, wherein
the light shielding structure having a wall shape further penetrates the first semiconductor layer.

4. The photodetection element according to claim 3, further comprising a second semiconductor layer configured on a side of the photoelectric conversion layer opposite to the light incident side, wherein
the light shielding structure having a wall shape further penetrates the second semiconductor layer.

5. The photodetection element according to claim 4, further comprising:
a plurality of first conductivity type regions to which signal charges generated in the photoelectric conversion layer move; and
a second conductivity type region provided between the light shielding structures having a wall shape adjacent to each other while penetrating the photoelectric conversion layer.

6. The photodetection element according to claim 5, wherein the photoelectric conversion layer is of a second conductivity type,
the second conductivity type region has a higher concentration than the photoelectric conversion layer, and
the second conductivity type region is formed in the second semiconductor layer.

7. The photodetection element according to claim 6, further comprising a transparent electrode configured on the light incident side of the photoelectric conversion layer, wherein
the light shielding structure having a wall shape penetrates the transparent electrode.

8. The photodetection element according to claim 2, wherein the insulating film includes any of silicon oxide (SiO₂), silicon nitride (SiN), aluminum oxide (Al₂O₃), and hafnium oxide (HfO₂).

9. The photodetection element according to claim 8, wherein a total film thickness of the insulating film is 50 to 300 nm.

10. The photodetection element according to claim 1, wherein the photoelectric conversion layer is of a first conductivity type.

11. The photodetection element according to claim 1, wherein a sidewall protective film is further provided between an inner wall in the through hole having a groove shape and the light shielding structure having a wall shape.

12. The photodetection element according to claim 11, wherein the sidewall protective film is an insulating film doped with phosphorus (P), and the insulating film doped with phosphorus (P) contains at least one of added silica nitrile (PSG: Phosphosilicate Glass), phosphorus nitride (PxNy), and phosphorus oxide (PxOy).

13. The photodetection element according to claim 11, wherein the sidewall protective film is an insulating film doped with phosphorus (P), and has a film thickness of 2 to 20 nm, and a doping concentration of phosphorus is, for example, 1e^{20˜22} cm⁻³.

14. The photodetection element according to claim 7, wherein the second conductivity type region and at least the second conductivity type region of the light shielding structure are electrically connected to a readout circuit unit.

15. The photodetection element according to claim 1, further comprising a color filter provided between the light shielding structures having a wall shape adjacent to each other while penetrating the photoelectric conversion layer.

16. The photodetection element according to claim 1, wherein an end of the light shielding structure on the light incident side has a region in which a cross-sectional area increases from an incident side toward an opposite side.

17. A photodetection element comprising:
a photoelectric conversion layer that has at least one of indium gallium arsenide (InGaAs) or indium phosphide (InP) and generates a signal charge in response to incidence of light;
a light shielding structure having a wall shape and formed in a through hole having a groove shape and penetrating the photoelectric conversion layer; and
a sidewall protective film formed between an inner wall in the through hole having a groove shape and the light shielding structure having a wall shape, wherein the sidewall protective film is an insulating film doped with phosphorus (P).

18. A method for manufacturing a photodetection element, the method comprising:
forming a first temporary substrate, an initial insulating film, a first semiconductor layer, a photoelectric conversion layer, a second semiconductor layer, a protective film, and a second temporary substrate in layers;
deleting the first temporary substrate and the initial insulating film;
forming a first insulating film on a surface side of the first semiconductor layer opposite to the photoelectric conversion layer;
forming a through hole having a groove shape and penetrating the second semiconductor layer, the photoelectric conversion layer, and the first semiconductor layer from the second semiconductor layer side and stopping at the first insulating film; and
forming a protective film having a wall shape and a light shielding body from the second semiconductor layer side in the through hole having a groove shape.

19. A method for manufacturing a photodetection element, the method comprising:
forming at least a temporary substrate, a protective film, a photoelectric conversion layer, and an insulating film;
forming a through hole having a groove shape and penetrating the insulating film and the photoelectric conversion layer from a side of the insulating film and stopping at the protective film;
forming a wall shape and a light shielding body from the side of the insulating film in the through hole having a groove shape; and
etching ends of the insulating film, the protective film, and the light shielding body so that the insulating film has a flat surface.

20. An electronic device comprising:
the photodetection element according to claim 1; and
an optical system that focuses light on the photodetection element.
